(19) United States
(12) Patent Application Publication
(10) Pub. No.: US 2026/0215244 A1
(43) Pub. Date: Jul. 23, 2026

(54) INTEGRATED CIRCUIT DEVICE

(71) Applicant: Samsung Electronics Co., Ltd., Suwon-si (KR)

(72) Inventors: Jinmyoung Lee, Suwon-si (KR); Chaelyoung Kim, Suwon-si (KR); Jeonil Lee, Suwon-si (KR)

(21) Appl. No.: 19/295,118

(22) Filed: Aug. 8, 2025

(30) Foreign Application Priority Data
Jan. 21, 2025 (KR) 10-2025-0008985

(51) Int. Cl. H01L 23/522

(52) U.S. Cl. CPC H10W 20/42

(57) ABSTRACT

An integrated circuit device includes a lower insulating film over a substrate, first and second lower metal wiring layers passing through the lower insulating film in a vertical direction and spaced apart from each other with a first local region of the lower insulating film therebetween, an insulating etch stop layer including a first portion covering the first local region, a via jumper contact unit including a first surface contacting the first lower metal wiring layer, a second surface contacting the second lower metal wiring layer, and a third surface between the first and second contact surfaces to contact the first portion of the insulating etch stop layer, and an upper metal wiring layer spaced apart from at least one of the first and second lower metal wiring layers in the vertical direction with the via jumper contact unit therebetween and integrally connected to the via jumper contact unit.

### CROSS-REFERENCE TO RELATED APPLICATION

This application is based on and claims priority under 35 U.S.C. § 119 to Korean Patent Application No. 10-2025-0008985, filed on Jan. 21, 2025, in the Korean Intellectual Property Office, the disclosure of which is incorporated by reference herein in its entirety.

### TECHNICAL FIELD

The disclosure relates to an integrated circuit device, and more particularly, to an integrated

circuit device including a metal wiring layer.

### BACKGROUND

Due to the advancement of electronics technology, integrated circuit devices have been rapidly down-scaled, and the line-widths and pitches of metal wiring layers in integrated circuit devices also have been micronized. Therefore, it is desired to improve the electrical reliability of metal wiring layers.

### SUMMARY

The disclosure provides an integrated circuit device having a structure capable of improving the electrical reliability of metal wiring layers.

According to an aspect of the disclosure, there is provided an integrated circuit device including a lower insulating film arranged over a substrate, a first lower metal wiring layer and a second lower metal wiring layer, which pass through the lower insulating film in a vertical direction and are spaced apart from each other in a first horizontal direction with a first local region of the lower insulating film therebetween, an insulating etch stop layer including a first portion that covers the first local region of the lower insulating film, a via jumper contact unit, which includes a first contact surface contacting the first lower metal wiring layer, a second contact surface contacting the second lower metal wiring layer, and a third contact surface spaced apart from the first local region of the lower insulating film in the vertical direction with the first portion of the insulating etch stop layer therebetween, the third contact surface being arranged between the first contact surface and the second contact surface and contacting the first portion of the insulating etch stop layer, and an upper metal wiring layer spaced apart from at least one of the first lower metal wiring layer and the second lower metal wiring layer in the vertical direction with the via jumper contact unit therebetween, the upper metal wiring layer being integrally connected to the via jumper contact unit.

According to another aspect of the disclosure, there is provided an integrated circuit device including a lower insulating film, a plurality of lower metal wiring layers, which pass through the lower insulating film in a vertical direction and are spaced apart from each other in a first horizontal direction, an upper insulating film covering the lower insulating film and the plurality of lower metal wiring layers, a via jumper contact unit including at least two contact portions and a contact connection portion, the at least two contact portions passing through the upper insulating film in the vertical direction and respectively contacting at least two lower metal wiring layers selected from the plurality of lower metal wiring layers, and the contact connection portion being integrally connected to the at least two contact portions and overlapping a local region of the lower insulating film in the vertical direction, and an insulating etch stop layer arranged between the local region of the lower insulating film and the contact connection portion of the via jumper contact unit.

According to another aspect of the disclosure, there is provided an integrated circuit device including a lower insulating film arranged over a substrate, a pair of lower metal wiring layers, which passes through the lower insulating film in a vertical direction and are spaced apart from each other in a first horizontal direction with a local region of the lower insulating film therebetween, an insulating etch stop layer selectively covering only an upper surface of the lower insulating film from among the upper surface of the lower insulating film and respective upper surfaces of the pair of lower metal wiring layers, an upper insulating film covering the lower insulating film, the pair of lower metal wiring layers, and the insulating etch stop layer, and a via jumper contact unit including a pair of contact portions and a contact connection portion, the pair of contact portions passing through the upper insulating film in the vertical direction and respectively contacting the pair of lower metal wiring layers, and the contact connection portion being integrally connected to the pair of contact portions and overlapping a local region of the lower insulating film in the vertical direction, wherein the insulating etch stop layer includes a first portion arranged between the local region of the lower insulating film and the contact connection portion of the via jumper contact unit, the first portion of the insulating etch stop layer being in contact with a lower surface of the contact connection portion of the via jumper contact unit.

### BRIEF DESCRIPTION OF THE DRAWINGS

Implementations will be more clearly understood from the following detailed description taken in conjunction with the accompanying drawings in which:

FIG. 1 is a planar layout diagram illustrating an integrated circuit device according to implementations;

FIG. 2A is a cross-sectional view of the integrated circuit device of FIG. 1, taken along a line X1-X1′ of FIG. 1;

FIG. 2B is a cross-sectional view of the integrated circuit device of FIG. 1, taken along a line Y1-Y1′ of FIG. 1;

FIG. 2C is an enlarged cross-sectional view of a region EX1 of FIG. 2A;

FIGS. 3 to 13 are cross-sectional views respectively illustrating integrated circuit devices according to some implementations;

FIGS. 14A and 14B are cross-sectional views illustrating an integrated circuit device according to some implementations;

FIGS. 15A, 15B, 16A, 16B, 17A, 17B, 18A, 18B, 19A, 19B, 20A, 20B, 21A, and 21B are cross-sectional views respectively illustrating a sequence of processes of a method of fabricating an integrated circuit device, according to implementations, and in particular, FIGS. 15A, 16A, 17A, 18A, 19A, 20A, and 21A are cross-sectional views of a region corresponding to a cross-section taken along the line X1-X1′ of FIG. 1, according to the sequence of processes, and FIGS. 15B, 16B, 17B, 18B, 19B, 20B, and 21B are cross-sectional views of a region corresponding to a cross-section taken along the line Y1-Y1′ of FIG. 1, according to the sequence of processes;

FIGS. 22A and 22B are cross-sectional views respectively illustrating a sequence of processes of a method of fabricating an integrated circuit device, according to some implementations;

FIGS. 23A, 23B, 23C, and 23D are cross-sectional views respectively illustrating a sequence of processes of a method of fabricating an integrated circuit device, according to some implementations;

FIG. 24 is a cross-sectional view illustrating a method of fabricating an integrated circuit device, according to some implementations; and

FIGS. 25A, 25B, 26A, 26B, 27A, and 27B are cross-sectional views respectively illustrating a sequence of processes of a method of fabricating an integrated circuit device, according to some implementations, and in particular, FIGS. 25A, 26A, and 27A are cross-sectional views of a region corresponding to the cross-section taken along the line X1-X1′ of FIG. 1, according to the sequence of processes, and FIGS. 25B, 26B, and 27B are cross-sectional views of a region corresponding to the cross-section taken along the line Y1-Y1′ of FIG. 1, according to the sequence of processes.

### DETAILED DESCRIPTION

Hereinafter, implementations of the disclosure will be described in detail with reference to the accompanying drawings. Like components are denoted by like reference numerals throughout the specification, and repeated descriptions thereof are omitted.

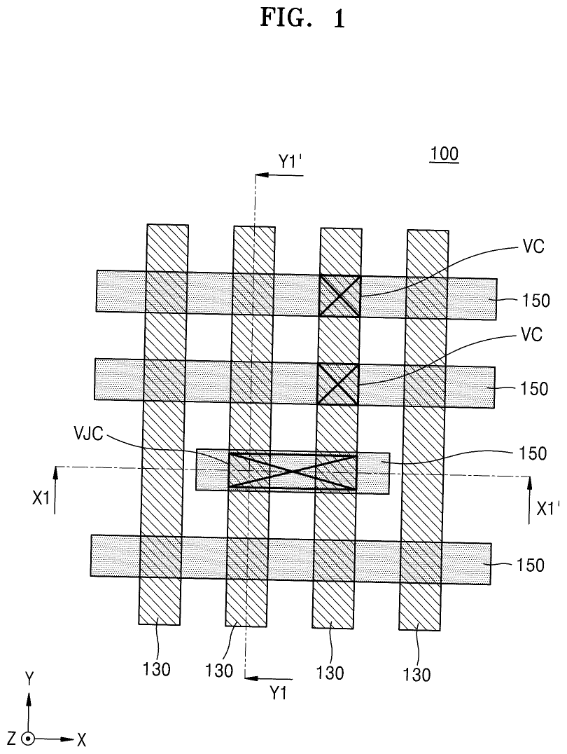

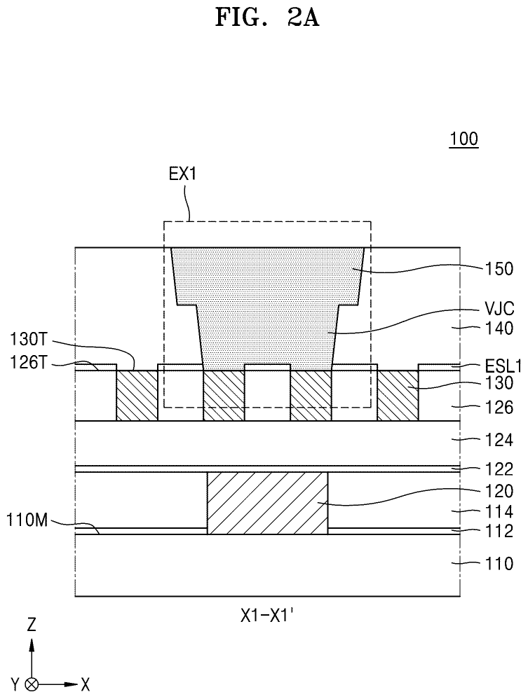

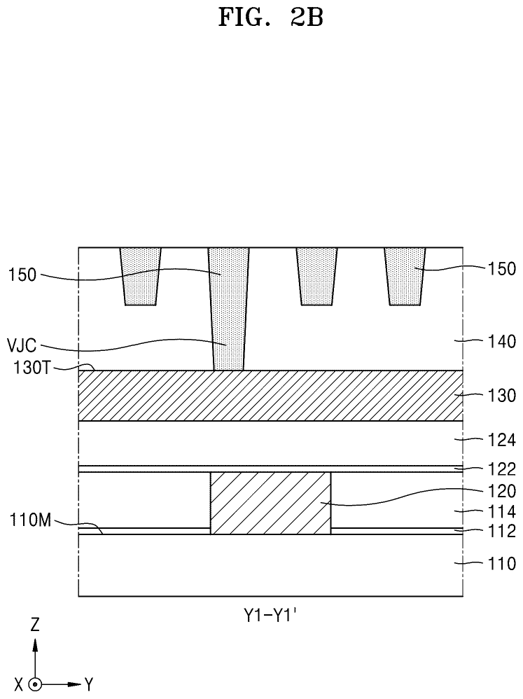

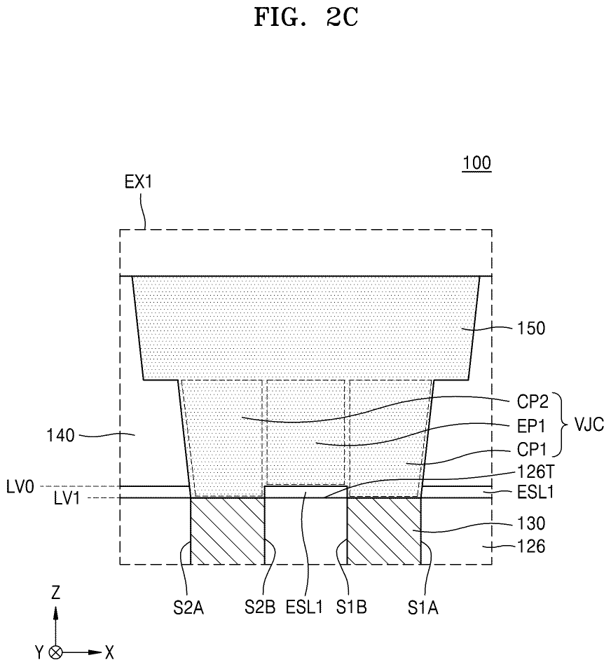

FIG. 1 is a planar layout diagram illustrating an integrated circuit device 100 according to implementations. FIG. 2A is a cross-sectional view of the integrated circuit device 100, taken along a line X1-X1′ of FIG. 1. FIG. 2B is a cross-sectional view of the integrated circuit device 100, taken along a line Y1-Y1′ of FIG. 1. FIG. 2C is an enlarged cross-sectional view of a region EX1 of FIG. 2A.

Referring to FIGS. 1 and 2A to 2C, the integrated circuit device 100 may include a lower structure arranged on a substrate 110. The lower structure may include a first lower etch stop layer 112, a first interlayer dielectric 114, a second lower etch stop layer 122, and a second interlayer dielectric 124, which are sequentially arranged in the stated order in a vertical direction (a Z direction) on the substrate 110, and may also include a conductive structure 120 that passes through the first interlayer dielectric 114 and the first lower etch stop layer 112 in the vertical direction (the Z direction).

The substrate 110 may include a semiconductor, such as Si or Ge, or a compound semiconductor, such as SiGe, SiC, GaAs, InAs, or InP. The substrate 110 may include a conductive region (not shown). The conductive region may include an impurity-doped well, an impurity-doped structure, or a conductive layer. The substrate 110 may include circuit elements (not shown), such as a gate structure, an impurity region, a contact plug, and the like.

Each of the first interlayer dielectric 114 and the second interlayer dielectric 124 may include a silicon oxide film. For example, each of the first interlayer dielectric 114 and the second interlayer dielectric 124 may include a silicon oxide-based material, such as plasma-enhanced oxide (PEOX), tetraethyl orthosilicate (TEOS), boro-TEOS (BTEOS), phosphorous TEOS (PTEOS), boro-phospho-TEOS (BPTEOS), boro-silicate glass (BSG), phospho-silicate glass (PSG), boro-phospho-silicate glass (BPSG), or the like. In some implementations, each of the first interlayer dielectric 114 and the second interlayer dielectric 124 may include a low-k dielectric film having a low dielectric constant (that is, K) of about 2.2 to about 3.0, for example, a SiOC film or a SiCOH film.

Each of the first lower etch stop layer 112 and the second lower etch stop layer 122 may include an insulating material having etch selectivity that is different from that of a constituent material of each of the first interlayer dielectric 114 and the second interlayer dielectric 124. In some implementations, each of the first lower etch stop layer 112 and the second lower etch stop layer 122 may include a silicon nitride film, a carbon-doped silicon nitride film, or a carbon-doped silicon oxynitride film. In some implementations, each of the first lower etch stop layer 112 and the second lower etch stop layer 122 may include an insulating metal oxide film, an insulating metal nitride film, or a combination thereof. For example, each of the first lower etch stop layer 112 and the second lower etch stop layer 122 may include an aluminum oxide film (an Al₂O₃ film), an aluminum nitride film (an AlN film), or a combination thereof.

In some implementations, the conductive structure 120 may include a wiring layer that includes a metal film and a conductive barrier film surrounding the metal film. In the conductive structure 120, the metal film may include Cu, W, Mo, Ru, Co, Al, or a combination thereof and the conductive barrier film may include a TiN film, a TaN film, a Co film, or a combination thereof, but the disclosure is not limited thereto. In some implementations, the conductive structure 120 may be configured to be electrically connected to a conductive region formed in the substrate 110. In some implementations, the conductive structure 120 may be configured to be connected to a source/drain region (not shown) or a gate electrode (not shown) of a transistor formed in the substrate 110.

A lower insulating film 126 may be arranged on the second interlayer dielectric 124, and a plurality of lower metal wiring layers 130 may pass through the lower insulating film 126 in the vertical direction (the Z direction). The plurality of lower metal wiring layers 130 may be arranged apart from each other in a first horizontal direction (an X direction) and may extend lengthwise in a second horizontal direction (a Y direction) intersecting with the first horizontal direction (the X direction). The first horizontal direction and the second horizontal direction lie in a horizontal plane. In some implementations, the first horizontal direction (the X direction) and the second horizontal direction (the Y direction) may be orthogonal to each other. The plurality of lower metal wiring layers 130 may extend in the second horizontal direction (the Y direction) so as to be parallel to each other.

The upper surface of each of the plurality of lower metal wiring layers 130 and the upper surface of the lower insulating film 126 may extend in a horizontal direction (the X direction and the Y direction). The upper surface of each lower metal wiring layers 130 and the upper surface of the lower insulating film 126 are at the same or similar vertical levels. As used herein, the term “vertical level” refers to a distance in the vertical direction (the Z direction or a-Z direction) from a reference surface, for example, a main surface 110M of the substrate 110.

The integrated circuit device 100 may include an insulating etch stop layer ESL1 selectively covering only an upper surface 126T of the lower insulating film 126 from the upper surface 126T of the lower insulating film 126 and an upper surface 130T of each of the plurality of lower metal wiring layers 130. The insulating etch stop layer ESL1 may not include a portion covering the plurality of lower metal wiring layers 130.

The insulating etch stop layer ESL1 may be covered by an upper insulating film 140. The insulating etch stop layer ESL1 may include an insulating material having etch selectivity that is different from that of a constituent material of each of the lower insulating film 126 and the upper insulating film 140. In some implementations, the insulating etch stop layer ESL1 may include a silicon nitride film, a carbon-doped silicon nitride film, or a carbon-doped silicon oxynitride film. In some implementations, the insulating etch stop layer ESL1 may include an insulating metal oxide film, an insulating metal nitride film, or a combination thereof.

The plurality of lower metal wiring layers 130 and the insulating etch stop layer ESL1 may be covered by the upper insulating film 140. The upper insulating film 140 may be in contact with a portion of the upper surface 130T of each of the plurality of lower metal wiring layers 130. The upper insulating film 140 may be spaced apart from the lower insulating film 126 with the insulating etch stop layer ESL1 therebetween.

The integrated circuit device 100 may include a plurality of upper metal wiring layers 150. Each of the plurality of upper metal wiring layers 150 may be arranged to overlap, in the vertical direction (the Z direction), at least one lower metal wiring layer 130 selected from the plurality of lower metal wiring layers 130. Each of the plurality of upper metal wiring layers 150 may extend lengthwise in the first horizontal direction (the X direction). Each of the plurality of upper metal wiring layers 150 may be configured to be electrically connected to at least one lower metal wiring layer 130, which is selected from the plurality of lower metal wiring layers 130, via a conductive contact plug VC or a via jumper contact unit VJC.

A pair of lower metal wiring layers 130 adjacent to each other from among the plurality of lower metal wiring layers 130 may be configured to be electrically connected to each other by the via jumper contact unit VJC. Herein, one lower metal wiring layer 130 selected from the pair of lower metal wiring layers 130 may be referred to as a first lower metal wiring layer, and the other lower metal wiring layer 130 may be referred to as a second lower metal wiring layer. The pair of lower metal wiring layers 130 may be spaced apart from each other in the first horizontal direction (the X direction) with a local region of the lower insulating film 126 therebetween. As shown in FIG. 2C, one lower metal wiring layer 130 (the first lower metal wiring layer) from the pair of lower metal wiring layers 130 may have a first outer sidewall S1A, which is farthest from the other lower metal wiring layer 130 (the second lower metal wiring layer) in the first horizontal direction (the X direction), and a first inner sidewall S1B, which faces the other lower metal wiring layer 130 (the second lower metal wiring layer) in the first horizontal direction (the X direction). The other lower metal wiring layer 130 (the second lower metal wiring layer) from the pair of lower metal wiring layers 130 may have a second outer sidewall S2A, which is farthest from the one lower metal wiring layer 130 (the first lower metal wiring layer) in the first horizontal direction (the X direction), and a second inner sidewall S2B, which faces the one lower metal wiring layer 130 (the first lower metal wiring layer) in the first horizontal direction (the X direction).

The via jumper contact unit VJC may include a first contact portion CP1 contacting the one lower metal wiring layer 130 (the first lower metal wiring layer) from the pair of lower metal wiring layers 130, a second contact portion CP2 contacting the other lower metal wiring layer 130 (the second lower metal wiring layer) from the pair of lower metal wiring layers 130, and a contact connection portion EP1 extending in the first horizontal direction (the X direction) between the first contact portion CP1 and the second contact portion CP2. The contact connection portion EP1 is integrally connected to both the first contact portion CP1 and the second contact portion CP2.

The first contact portion CP1 of the via jumper contact unit VJC may include a first contact surface contacting the upper surface 130T of the one lower metal wiring layer 130 (the first lower metal wiring layer) from the pair of lower metal wiring layers 130. The second contact portion CP2 of the via jumper contact unit VJC may include a second contact surface contacting the upper surface 130T of the other lower metal wiring layer 130 (the second lower metal wiring layer) from the pair of lower metal wiring layers 130. The contact connection portion EP1 of the via jumper contact unit VJC may include a third contact surface contacting a first portion of the insulating etch stop layer ESL1, the first portion covering the upper surface 126T of the local region of the lower insulating film 126 arranged between the pair of lower metal wiring layers 130. The via jumper contact unit VJC may contact the upper surface 130T of each of the pair of lower metal wiring layers 130 connected to the via jumper contact unit VJC. However, the via jumper contact unit VJC may not contact the sidewalls of each of the pair of lower metal wiring layers 130, for example, the first outer sidewall S1A, the first inner sidewall S1B, the second outer sidewall S2A, and the second inner sidewall S2B.

The contact connection portion EP1 of the via jumper contact unit VJC may be arranged to overlap the lower insulating film 126 in the vertical direction (the Z direction). The local region of the lower insulating film 126, which is arranged between the pair of lower metal wiring layers 130 connected to the via jumper contact unit VJC, is covered by the insulating etch stop layer ESL1. When an etching process for preparing a space, in which the via jumper contact unit VJC is to be located, is performed in a fabrication process of the integrated circuit device 100, the lower insulating film 126 between the pair of lower metal wiring layers 130 may be prevented from being unintentionally consumed and recessed. In addition, a vertical level of the lower surface of the contact connection portion EP1 of the via jumper contact unit VJC may be stably controlled by the insulating etch stop layer ESL1 contacting the contact connection portion EP1, and thus, the possibility of an unintended short-circuit between the via jumper contact unit VJC and another conductive component that is at a lower vertical level than the plurality of lower metal wiring layers 130, over the substrate 110, may be suppressed.

In the integrated circuit device 100, a vertical level LV0 of the uppermost surface of the insulating etch stop layer ESL1 may be higher than a vertical level LV1 of the uppermost surface of each of the plurality of lower metal wiring layers 130. Therefore, in the via jumper contact unit VJC, a vertical level of the third contact surface, which contacts the insulating etch stop layer ESL1, of the contact connection portion EP1 may be higher than a vertical level of each of the first contact surface of the first contact portion CP1 and the second contact surface of the second contact portion CP2. That is, the vertical level of the third contact surface, which contacts the insulating etch stop layer ESL1, of the contact connection portion EP1 may be farther from the substrate 110 than the vertical level of each of the first contact surface of the first contact portion CP1 and the second contact surface of the second contact portion CP2.

The plurality of upper metal wiring layers 150 may include one upper metal wiring layer 150 integrally connected to the via jumper contact unit VJC. Among the plurality of upper metal wiring layers 150, the upper surface of the one upper metal wiring layer 150, which is integrally connected to the via jumper contact unit VJC, and the upper surface of each of the remaining upper metal wiring layers 150 may be at the same vertical level. The one upper metal wiring layer 150 integrally connected to the via jumper contact unit VJC may be spaced apart from the pair of lower metal wiring layers 130, which are connected to the via jumper contact unit VJC, in the vertical direction (the Z direction) with the via jumper contact unit VJC therebetween. The one upper metal wiring layer 150 integrally connected to the via jumper contact unit VJC may include portions overlapping, in the vertical direction (the Z direction), each of the pair of lower metal wiring layers 130 connected to the via jumper contact unit VJC.

Each of the via jumper contact unit VJC and the upper metal wiring layer 150, which are integrally connected to each other, may have a cross-sectional shape that has a gradually increasing width in the first horizontal direction (the X direction) with an increasing distance from the lower insulating film 126 in the vertical direction (the Z direction). That is, each of the via jumper contact unit VJC and the upper metal wiring layer 150, which are integrally connected to each other, may have a decreasing width in the first horizontal direction (the X direction) with a decreasing distance from the substrate 110.

A constituent material of each of the lower insulating film 126 and the upper insulating film 140 is substantially the same as the constituent material of each of the first interlayer dielectric 114 and the second interlayer dielectric 124 described above. The plurality of lower metal wiring layers 130, the plurality of upper metal wiring layers 150, the via jumper contact unit VJC, and a plurality of conductive contact plugs VC may each include a metal film, a conductive metal nitride film, or a combination thereof. In some implementations, the plurality of lower metal wiring layers 130, the plurality of upper metal wiring layers 150, the via jumper contact unit VJC, and the plurality of conductive contact plugs VC may each include a metal plug and a conductive barrier film that surrounds the sidewall and the lower surface of the metal plug. The metal plug may include Cu, W, Mo, Ru, Co, Al, or a combination thereof. For example, the metal plug may include Cu. The conductive barrier film may include a TiN film, a TaN film, a Co film, or a combination thereof. For example, when the metal plug includes Cu, the conductive barrier film may include a multilayer structure including a TaN film and a Co film, but the disclosure is not limited thereto.

In the integrated circuit device 100 described with reference to FIGS. 1 and 2A to 2C, the insulating etch stop layer ESL1 is arranged between the contact connection portion EP1 of the via jumper contact unit VJC and the local region of the lower insulating film 126. The local region is located between the pair of lower metal wiring layers 130 connected to the via jumper contact unit VJC, and the lower surface, which faces the lower insulating film 126, of the contact connection portion EP1 of the via jumper contact unit VJC is in contact with the insulating etch stop layer ESL1. The local region of the lower insulating film 126, which is located between the pair of lower metal wiring layers 130 connected to the via jumper contact unit VJC, is covered by the insulating etch stop layer ESL1. Accordingly, when an etching process for preparing a space, in which the via jumper contact unit VJC is to be located, is performed in the fabrication process of the integrated circuit device 100, the lower insulating film 126 between the pair of lower metal wiring layers 130 may be prevented from being unintentionally consumed and recessed. In addition, the vertical level of the lower surface of the contact connection portion EP1 of the via jumper contact unit VJC may be stably controlled by the insulating etch stop layer ESL1 contacting the contact connection portion EP1, and thus, the possibility of an unintended short-circuit between the via jumper contact unit VJC and another conductive component that is at a lower vertical level than the plurality of lower metal wiring layers 130 may be suppressed.

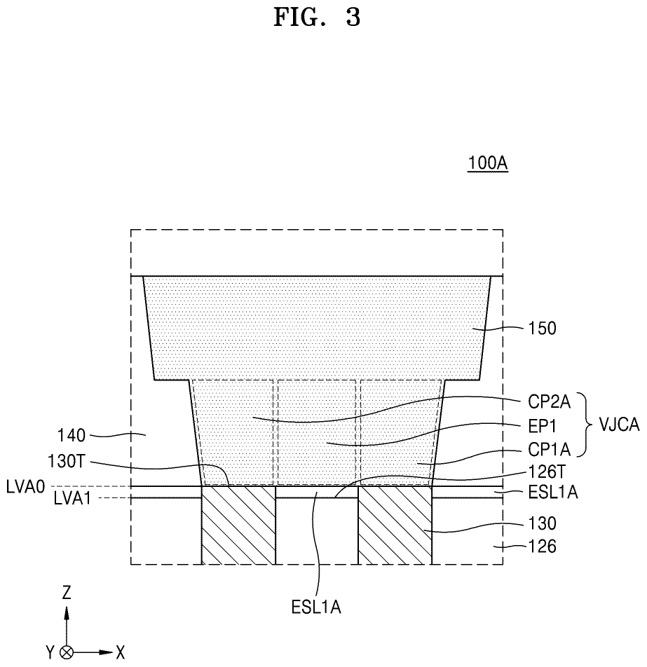

FIGS. 3 to 13 are cross-sectional views respectively illustrating integrated circuit devices 100A, 100B, 100C, 100D, 100E, 100F, 100G, 100H, 200, 200A, and 300 according to some implementations. FIGS. 3 to 13 respectively illustrate cross-sectional configurations of portions of the integrated circuit devices 100A, 100B, 100C, 100D, 100E, 100F, 100G, 100H, 200, 200A, and 300, the portions corresponding to the region EX1 of FIG. 2A. In FIGS. 3 to 13, the same reference numerals as in FIGS. 1 and 2A to 2C respectively denote the same members, and here, repeated descriptions thereof are omitted.

Referring to FIG. 3, the integrated circuit device 100A has substantially the same configuration as the integrated circuit device 100 described with reference to FIGS. 1 and 2A to 2C. However, the integrated circuit device 100A includes a via jumper contact unit VJCA connected to a pair of lower metal wiring layers 130 adjacent to each other from among the plurality of lower metal wiring layers 130. One upper metal wiring layer 150 from among the plurality of upper metal wiring layers 150 (see FIG. 1) may be integrally connected to the via jumper contact unit VJCA.

The via jumper contact unit VJCA may be in contact with the upper surface 130T of each of the pair of lower metal wiring layers 130, which are adjacent to each other, and the upper surface of an insulating etch stop layer ESL1A that is arranged between the pair of lower metal wiring layers 130 and covers the upper surface of the lower insulating film 126. More specifically, the via jumper contact unit VJCA may include a first contact portion CP1A contacting the upper surface 130T of one lower metal wiring layer 130 from the pair of lower metal wiring layers 130 adjacent to each other, a second contact portion CP2A contacting the upper surface 130T of the other lower metal wiring layer 130 from the pair of lower metal wiring layers 130, and a contact connection portion EP1 extending in the first horizontal direction (the X direction) between the first contact portion CP1A and the second contact portion CP2A and integrally connected to both the first contact portion CP1A and the second contact portion CP2A.

In the via jumper contact unit VJCA, the lower surface of the first contact portion CP1A, the lower surface of the second contact portion CP2A, and the lower surface of the contact connection portion EP1 may extend in the horizontal direction (the X direction and the Y direction). The lower surface of the first contact portion CP1A, the lower surface of the second contact portion CP2A, and the lower surface of the contact connection portion EP1 are at the same or similar vertical levels. More detailed configurations of the first contact portion CP1A and the second contact portion CP2A are respectively and substantially the same as those of the first contact portion CP1 and the second contact portion CP2, which are described with reference to FIGS. 2A and 2C.

The integrated circuit device 100A may include the insulating etch stop layer ESL1A, which selectively covers only the upper surface 126T of the lower insulating film 126 from the upper surface 126T of the lower insulating film 126 and the upper surface 130T of each of the plurality of lower metal wiring layers 130. The insulating etch stop layer ESL1A may not include a portion covering the upper surfaces of the plurality of lower metal wiring layers 130. The contact connection portion EP1 of the via jumper contact unit VJCA may be in contact with the upper surface of the insulating etch stop layer ESL1A while located to overlap (e.g., being arranged over), in the vertical direction (the Z direction), a local region of the lower insulating film 126 that is arranged between the pair of lower metal wiring layers 130 connected to the via jumper contact unit VJCA.

More detailed configurations of the via jumper contact unit VJCA and the insulating etch stop layer ESL1A are respectively and substantially similar to those of the via jumper contact unit VJC and the insulating etch stop layer ESL1, which are described with reference to FIGS. 1 and 2A to 2C. However, a vertical level LVA0 of the uppermost surface of the insulating etch stop layer ESL1A may be equal to or similar to the vertical level of the uppermost surface of each of the plurality of lower metal wiring layers 130. Therefore, in the via jumper contact unit VJCA, a vertical level of a contact surface, which contacts the insulating etch stop layer ESL1A, of the contact connection portion EP1, a vertical level of a contact surface, which contacts the upper surface 130T of the lower metal wiring layer 130, of the first contact portion CP1A, and a vertical level of a contact surface, which contacts the upper surface 130T of the lower metal wiring layer 130, of the second contact portion CP2A may be equal to or similar to each other. In the integrated circuit device 100A, a vertical level LVA1 of the upper surface 126T of the lower insulating film 126 surrounding the plurality of lower metal wiring layers 130 may be lower than the vertical level LVA0 of the uppermost surface of the insulating etch stop layer ESL1A and may be lower than the vertical level of the uppermost surface of each of the plurality of lower metal wiring layers 130. Therefore, in the integrated circuit device 100A, an upper portion of each of the plurality of lower metal wiring layers 130 may protrude in the vertical direction (the Z direction) above the upper surface 126T of the lower insulating film 126.

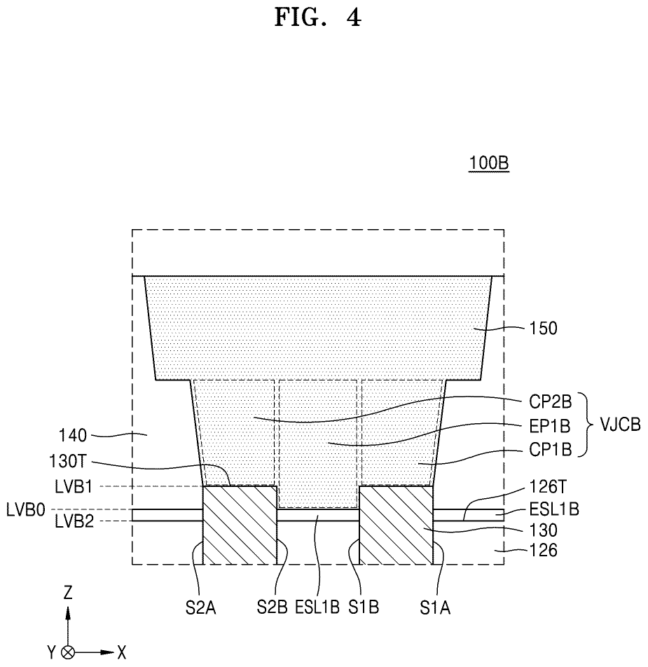

Referring to FIG. 4, the integrated circuit device 100B has substantially the same configuration as the integrated circuit device 100 described with reference to FIGS. 1 and 2A to 2C. However, the integrated circuit device 100B includes a via jumper contact unit VJCB connected to a pair of lower metal wiring layers 130 adjacent to each other from among the plurality of lower metal wiring layers 130. One upper metal wiring layer 150 from among the plurality of upper metal wiring layers 150 (see FIG. 1) may be integrally connected to the via jumper contact unit VJCB.

The via jumper contact unit VJCB may be in contact with the upper surface 130T of each of the pair of lower metal wiring layers 130, at least one sidewall of each of the pair of lower metal wiring layers 130, and the upper surface of an insulating etch stop layer ESL1B that is arranged between the pair of lower metal wiring layers 130 and covers the upper surface of the lower insulating film 126. More specifically, the via jumper contact unit VJCB may include a first contact portion CP1B contacting the upper surface 130T of one lower metal wiring layer 130 from the pair of lower metal wiring layers 130 adjacent to each other, a second contact portion CP2B contacting the upper surface 130T of the other lower metal wiring layer 130 from the pair of lower metal wiring layers 130, and a contact connection portion EP1B extending in the first horizontal direction (the X direction) between the first contact portion CP1B and the second contact portion CP2B and integrally connected to both the first contact portion CP1B and the second contact portion CP2B. The contact connection portion EP1B of the via jumper contact unit VJCB may include a contact surface, which contacts the first inner sidewall S1B of the one lower metal wiring layer 130, and a contact surface, which contacts the second inner sidewall S2B of the other lower metal wiring layer 130. More detailed configurations of the first contact portion CP1B, the second contact portion CP2B, and the contact connection portion EP1B are respectively and substantially the same as those of the first contact portion CP1, the second contact portion CP2, and the contact connection portion EP1, which are described with reference to FIGS. 2A and 2C.

In the integrated circuit device 100B, the insulating etch stop layer ESL1B may selectively cover only the upper surface 126T of the lower insulating film 126 from the upper surface 126T of the lower insulating film 126 and the upper surface 130T of each of the plurality of lower metal wiring layers 130. The insulating etch stop layer ESL1B may not include a portion covering the upper surfaces of the plurality of lower metal wiring layers 130. The contact connection portion EP1B of the via jumper contact unit VJCB may be in contact with the upper surface of the insulating etch stop layer ESL1B while located to overlap (e.g., arranged over), in the vertical direction (the Z direction), a local region of the lower insulating film 126 that is arranged between the pair of lower metal wiring layers 130 connected to the via jumper contact unit VJCB.

More detailed configurations of the via jumper contact unit VJCB and the insulating etch stop layer ESL1B are respectively and substantially similar to those of the via jumper contact unit VJC and the insulating etch stop layer ESL1, which are described with reference to FIGS. 1 and 2A to 2C. However, a vertical level LVB0 of the uppermost surface of the insulating etch stop layer ESL1B may be lower than the vertical level of the uppermost surface of each of the plurality of lower metal wiring layers 130. Therefore, in the via jumper contact unit VJCB, a vertical level of a contact surface, which contacts the upper surface of the insulating etch stop layer ESL1B, of the contact connection portion EP1B may be lower than a vertical level of a contact surface, which contacts the upper surface 130T of the lower metal wiring layer 130, of the first contact portion CP1B, and may also be lower than a vertical level of a contact surface, which contacts the upper surface 130T of the lower metal wiring layer 130, of the second contact portion CP2B. In the via jumper contact unit VJCB, the vertical level of the contact surface, which contacts the insulating etch stop layer ESL1B, of the contact connection portion EP1B may be closer to the substrate 110 than the vertical level of the contact surface, which contacts the upper surface 130T of the lower metal wiring layer 130, of the first contact portion CP1B and the vertical level of the contact surface, which contacts the upper surface 130T of the lower metal wiring layer 130, of the second contact portion CP2B.

In the integrated circuit device 100B, a vertical level LVB2 of the upper surface 126T of the lower insulating film 126 surrounding the plurality of lower metal wiring layers 130 may be lower than the vertical level LVB0 of the uppermost surface of the insulating etch stop layer ESL1B. Therefore, in the integrated circuit device 100B, an upper portion of each of the plurality of lower metal wiring layers 130 may protrude in the vertical direction (the Z direction) above the upper surface 126T of the lower insulating film 126.

In the integrated circuit device 100B, the upper insulating film 140 may include portions covering sidewalls of the via jumper contact unit VJCB and sidewalls of the upper metal wiring layer 150 integrally connected to the via jumper contact unit VJCB, portions contacting the upper surface of the insulating etch stop layer ESL1B, a portion contacting the first outer sidewall S1A of one lower metal wiring layer 130 from a pair of lower metal wiring layers 130 connected to the via jumper contact unit VJCB, and a portion contacting the second outer sidewall S2A of the other lower metal wiring layer 130 from the pair of lower metal wiring layers 130.

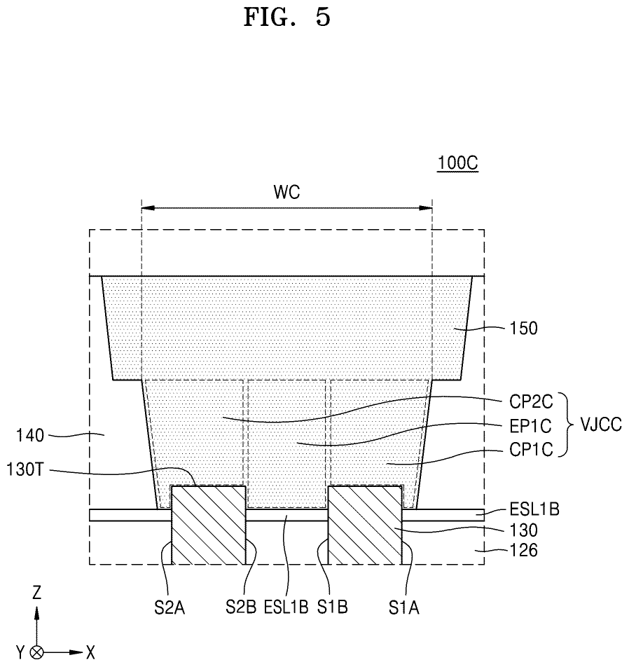

Referring to FIG. 5, the integrated circuit device 100C has substantially the same configuration as the integrated circuit device 100B described with reference to FIG. 4. However, the integrated circuit device 100C includes a via jumper contact unit VJCC connected to a pair of lower metal wiring layers 130 adjacent to each other from among the plurality of lower metal wiring layers 130. One upper metal wiring layer 150 from among the plurality of upper metal wiring layers 150 (see FIG. 1) may be integrally connected to the via jumper contact unit VJCC.

The via jumper contact unit VJCC may be in contact with the upper surface 130T of each of the pair of lower metal wiring layers 130, both sidewalls of each of the pair of lower metal wiring layers 130 in terms of the first horizontal direction (the X direction), and the upper surface of the insulating etch stop layer ESL1B that is arranged between the pair of lower metal wiring layers 130 and covers the upper surface of the lower insulating film 126. For example, the via jumper contact unit VJCC may be in contact with the upper surface 130T, the first outer sidewall S1A, and the first inner sidewall S1B of one lower metal wiring layer 130 from the pair of lower metal wiring layers 130 and may be in contact with the upper surface 130T, the second outer sidewall S2A, and the second inner sidewall S2B of the other lower metal wiring layer 130 from the pair of lower metal wiring layers 130. More specifically, the via jumper contact unit VJCC may include a first contact portion CP1C contacting the upper surface 130T and the first outer sidewall S1A of the one lower metal wiring layer 130 from the pair of lower metal wiring layers 130 adjacent to each other, a second contact portion CP2C contacting the upper surface 130T and the second outer sidewall S2A of the other lower metal wiring layer 130 from the pair of lower metal wiring layers 130, and a contact connection portion EP1C extending in the first horizontal direction (the X direction) between the first contact portion CP1C and the second contact portion CP2C and integrally connected to both the first contact portion CP1C and the second contact portion CP2C. The contact connection portion EP1C of the via jumper contact unit VJCC may include a contact surface, which contacts the first inner sidewall S1B of the one lower metal wiring layer 130, and a contact surface, which contacts the second inner sidewall S2B of the other lower metal wiring layer 130. More detailed configurations of the first contact portion CP1C, the second contact portion CP2C, and the contact connection portion EP1C are respectively and substantially the same as those of the first contact portion CP1, the second contact portion CP2, and the contact connection portion EP1, which are described with reference to FIGS. 2A and 2C.

In the integrated circuit device 100C, a width WC of the via jumper contact unit VJCC in the first horizontal direction (the X direction) may be greater than the distance in the first horizontal direction (the X direction) between the first outer sidewall S1A of the one lower metal wiring layer 130 from the pair of lower metal wiring layers 130 and the second outer sidewall S2A of the other lower metal wiring layer 130. According to the integrated circuit device 100C, the contact area between the via jumper contact unit VJCC and each of the plurality of lower metal wiring layers 130 connected to the via jumper contact unit VJCC may be relatively increased, and thus, the contact resistance between the via jumper contact unit VJCC and the plurality of lower metal wiring layers 130 connected to the via jumper contact unit VJCC may be relatively reduced.

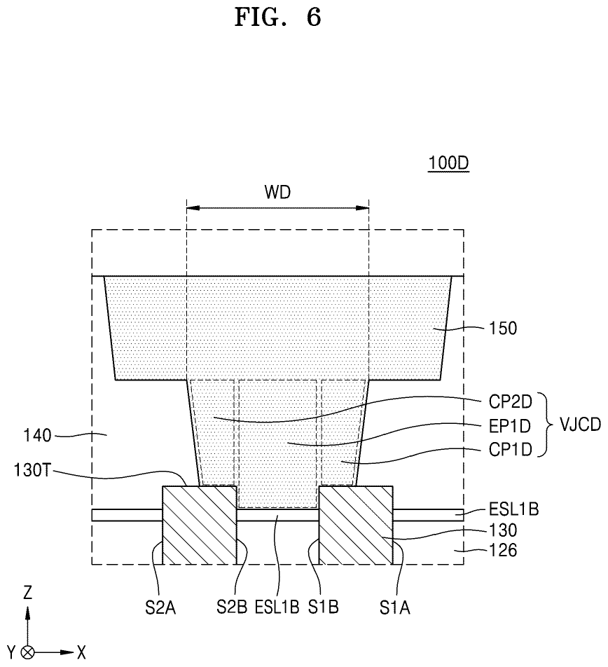

Referring to FIG. 6, the integrated circuit device 100D has substantially the same configuration as the integrated circuit device 100B described with reference to FIG. 4. However, the integrated circuit device 100D includes a via jumper contact unit VJCD connected to a pair of lower metal wiring layers 130 adjacent to each other from among the plurality of lower metal wiring layers 130. One upper metal wiring layer 150 from among the plurality of upper metal wiring layers 150 (see FIG. 1) may be integrally connected to the via jumper contact unit VJCD.

The via jumper contact unit VJCD may be in contact with the upper surface 130T and at least one sidewall of each of the pair of lower metal wiring layers 130 and the upper surface of the insulating etch stop layer ESL1B that is arranged between the pair of lower metal wiring layers 130 and covers the upper surface of the lower insulating film 126. For example, the via jumper contact unit VJCD may be in contact with the upper surface 130T and the first inner sidewall S1B of one lower metal wiring layer 130 from the pair of lower metal wiring layers 130 and may be in contact with the upper surface 130T and the second inner sidewall S2B of the other lower metal wiring layer 130 from the pair of lower metal wiring layers 130. More specifically, the via jumper contact unit VJCD may include a first contact portion CP1D contacting the upper surface 130T of the one lower metal wiring layer 130 from the pair of lower metal wiring layers 130 adjacent to each other, a second contact portion CP2D contacting the upper surface 130T of the other lower metal wiring layer 130 from the pair of lower metal wiring layers 130, and a contact connection portion EP1D extending in the first horizontal direction (the X direction) between the first contact portion CP1D and the second contact portion CP2D and integrally connected to each of the first contact portion CP1D and the second contact portion CP2D. The contact connection portion EP1D of the via jumper contact unit VJCD may include a contact surface, which contacts the first inner sidewall S1B of the one lower metal wiring layer 130, and a contact surface, which contacts the second inner sidewall S2B of the other lower metal wiring layer 130. More detailed configurations of the first contact portion CP1D, the second contact portion CP2D, and the contact connection portion EP1D are respectively and substantially the same as those of the first contact portion CP1, the second contact portion CP2, and the contact connection portion EP1, which are described with reference to FIGS. 2A and 2C.

In the integrated circuit device 100D, a width WD of the via jumper contact unit VJCD in the first horizontal direction (the X direction) may be less than the distance in the first horizontal direction (the X direction) between the first outer sidewall S1A of the one lower metal wiring layer 130 from the pair of lower metal wiring layers 130 and the second outer sidewall S2A of the other lower metal wiring layer 130. The via jumper contact unit VJCD may be spaced apart from the first outer sidewall S1A of the one lower metal wiring layer 130 from the pair of lower metal wiring layers 130 contacting the via jumper contact unit VJCD and may be spaced apart from the second outer sidewall S2A of the other lower metal wiring layer 130 from the pair of lower metal wiring layers 130.

In the integrated circuit device 100D, the upper insulating film 140 may include portions covering sidewalls of the via jumper contact unit VJCD and sidewalls of the upper metal wiring layer 150 integrally connected to the via jumper contact unit VJCD, portions contacting the upper surface of the insulating etch stop layer ESL1B, a portion contacting the upper surface 130T and the first outer sidewall S1A of the one lower metal wiring layer 130 from the pair of lower metal wiring layers 130 connected to the via jumper contact unit VJCD, and a portion contacting the upper surface 130T and the second outer sidewall S2A of the other lower metal wiring layer 130 from the pair of lower metal wiring layers 130.

According to the integrated circuit device 100D, the width WD of the via jumper contact unit VJCD in the first horizontal direction (the X direction) is relatively small and the via jumper contact unit VJCD has a shape having a gradually decreasing width in the first horizontal direction (the X direction) with a decreasing distance from the lower metal wiring layer 130 in the vertical direction (the Z direction). Accordingly, the contact area between the via jumper contact unit VJCD and the pair of lower metal wiring layers 130 connected to the via jumper contact unit VJCD may be secured, and simultaneously, the possibility of an unintended short-circuit between the via jumper contact unit VJCD and another lower metal wiring layer 130 that is adjacent to the pair of lower metal wiring layers 130 may be reduced or eliminated.

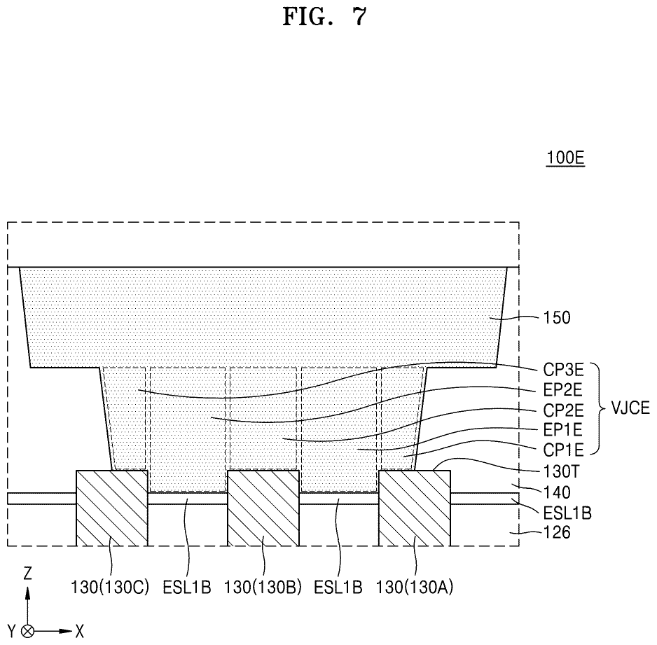

Referring to FIG. 7, the integrated circuit device 100E has substantially the same configuration as the integrated circuit device 100B described with reference to FIG. 4. However, the integrated circuit device 100E includes a via jumper contact unit VJCE connected to three lower metal wiring layers 130 adjacent to each other from among the plurality of lower metal wiring layers 130. One upper metal wiring layer 150 from among the plurality of upper metal wiring layers 150 (see FIG. 1) may be integrally connected to the via jumper contact unit VJCE. A local region of the lower insulating film 126 may be arranged between each of the three lower metal wiring layers 130, and the upper surface of each of the local regions of the lower insulating film 126, which are between each of the three lower metal wiring layers 130, may be covered by the insulating etch stop layer ESL1B.

The insulating etch stop layer ESL1B may include a portion that is arranged between a first lower metal wiring layer 130A and a second lower metal wiring layer 130B, which are selected from the three lower metal wiring layers 130, and that covers a local region of the lower insulating film 126. Further, the insulating etch stop layer ESL1B may include a portion that is arranged between the second lower metal wiring layer 130B and a third lower metal wiring layer 130C, which are selected from the three lower metal wiring layers 130, and that covers another local region of the lower insulating film 126.

The via jumper contact unit VJCE may be in contact with the upper surface 130T and at least one sidewall of each of the three lower metal wiring layers 130 and the upper surface of the insulating etch stop layer ESL1B that is arranged between each of the three lower metal wiring layers 130 and covers the upper surface of the lower insulating film 126. For example, the via jumper contact unit VJCE may be in contact with the upper surface and one sidewall of the first lower metal wiring layer 130A, in contact with the upper surface and both sidewalls, in terms of the first horizontal direction (the X direction), of the second lower metal wiring layer 130B, and in contact with the upper surface and one sidewall of the third lower metal wiring layer 130C.

More specifically, the via jumper contact unit VJCE may include a first contact portion CP1E having a contact surface contacting the upper surface 130T of the first lower metal wiring layer 130A, a second contact portion CP2E having a contact surface contacting the upper surface 130T of the second lower metal wiring layer 130B, a third contact portion CP3E having a contact surface contacting the upper surface 130T of the third lower metal wiring layer 130C, a first contact connection portion EP1E extending in the first horizontal direction (the X direction) between the first contact portion CP1E and the second contact portion CP2E and integrally connected to both the first contact portion CP1E and the second contact portion CP2E, and a second contact connection portion EP2E extending in the first horizontal direction (the X direction) between the second contact portion CP2E and the third contact portion CP3E and integrally connected to each of the second contact portion CP2E and the third contact portion CP3E. The first contact connection portion EP1E of the via jumper contact unit VJCE may have a contact surface contacting one sidewall of the first lower metal wiring layer 130A, a contact surface arranged between the first lower metal wiring layer 130A and the second lower metal wiring layer 130B and contacting the upper surface of a first portion of the insulating etch stop layer ESL1B, and a contact surface contacting one sidewall of the second lower metal wiring layer 130B. The second contact connection portion EP2E of the via jumper contact unit VJCE may have a contact surface contacting the other sidewall of the second lower metal wiring layer 130B, a contact surface arranged between the second lower metal wiring layer 130B and the third lower metal wiring layer 130C and contacting the upper surface of a second portion of the insulating etch stop layer ESL1B, and a contact surface contacting one sidewall of the third lower metal wiring layer 130C. A more detailed configuration of the via jumper contact unit VJCE is substantially the same as the via jumper contact unit VJC described with reference to FIGS. 2A and 2C.

In the integrated circuit device 100E, the upper insulating film 140 may include portions covering sidewalls of the via jumper contact unit VJCE and sidewalls of the upper metal wiring layer 150 integrally connected to the via jumper contact unit VJCE, portions contacting the upper surface of the insulating etch stop layer ESL1B, and portions contacting the upper surface 130T and a sidewall of each of the first lower metal wiring layer 130A and the third lower metal wiring layer 130C from among the three lower metal wiring layers 130 connected to the via jumper contact unit VJCE.

According to the integrated circuit device 100E, the width of the via jumper contact unit VJCE in the first horizontal direction (the X direction) is less than the width, in the first horizontal direction (the X direction), of a region occupied by the plurality of lower metal wiring layers 130 connected to the via jumper contact unit VJCE, and the via jumper contact unit VJCE has a shape having a gradually decreasing width in the first horizontal direction (the X direction) with a decreasing distance from the lower metal wiring layer 130 in the vertical direction (the Z direction). Accordingly, the contact area between the via jumper contact unit VJCE and lower metal wiring layers 130 connected to the via jumper contact unit VJCE may be secured, and simultaneously, the possibility of an unintended short-circuit between the via jumper contact unit VJCE and another lower metal wiring layer 130 that is adjacent to the lower metal wiring layers 130 connected to the via jumper contact unit VJCE may be reduced or eliminated.

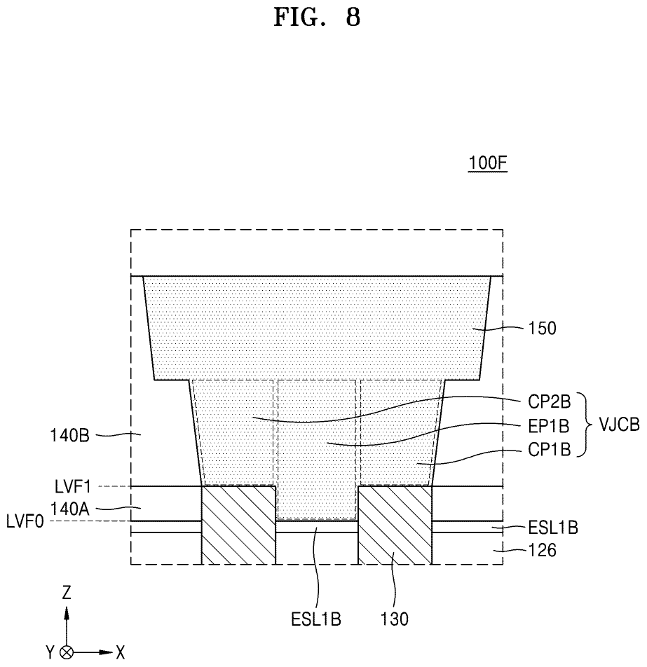

Referring to FIG. 8, the integrated circuit device 100F has substantially the same configuration as the integrated circuit device 100B described with reference to FIG. 4. However, the integrated circuit device 100F includes a first upper insulating film 140A, which is arranged on the insulating etch stop layer ESL1B, and a second upper insulating film 140B, which is arranged on the first upper insulating film 140A.

The first upper insulating film 140A may be in contact with the upper surface of the insulating etch stop layer ESL1B and an upper sidewall of each of the plurality of lower metal wiring layers 130. The second upper insulating film 140B may be in contact with the upper surface of the first upper insulating film 140A. The second upper insulating film 140B may cover the sidewalls of the via jumper contact unit VJCB and the sidewalls of the upper metal wiring layer 150 integrally connected to the via jumper contact unit VJCB. In some implementations, the first upper insulating film 140A and the second upper insulating film 140B may include the same material. In some implementations, the first upper insulating film 140A and the second upper insulating film 140B may respectively include different materials. A constituent material of each of the first upper insulating film 140A and the second upper insulating film 140B is substantially the same as the constituent material of each of the first interlayer dielectric 114 and the second interlayer dielectric 124 described with reference to FIGS. 2A to 2C.

In the integrated circuit device 100F, a vertical level LVF0 of the uppermost surface of the insulating etch stop layer ESL1B may be lower than a vertical level LVF1 of the uppermost surface of each of the plurality of lower metal wiring layers 130. A vertical level of the upper surface of the first upper insulating film 140A may be equal to or similar to the vertical level LVF1 of the uppermost surface of each of the plurality of lower metal wiring layers 130.

In the via jumper contact unit VJCB of the integrated circuit device 100F, a vertical level of a contact surface, which contacts the upper surface of the insulating etch stop layer ESL1B, of the contact connection portion EP1B may be lower than a vertical level of a contact surface, which contacts the upper surface 130T of the lower metal wiring layer 130, of the first contact portion CP1B and may be lower than a vertical level of a contact surface, which contacts the upper surface 130T of the lower metal wiring layer 130, of the second contact portion CP2B. In the via jumper contact unit VJCB of the integrated circuit device 100F, the vertical level of the contact surface, which contacts the insulating etch stop layer ESL1B, of the contact connection portion EP1B may be closer to the substrate 110 than the vertical level of each of the contact surface, which contacts the upper surface 130T of the lower metal wiring layer 130, of the first contact portion CP1B and the contact surface, which contacts the upper surface 130T of the lower metal wiring layer 130, of the second contact portion CP2B.

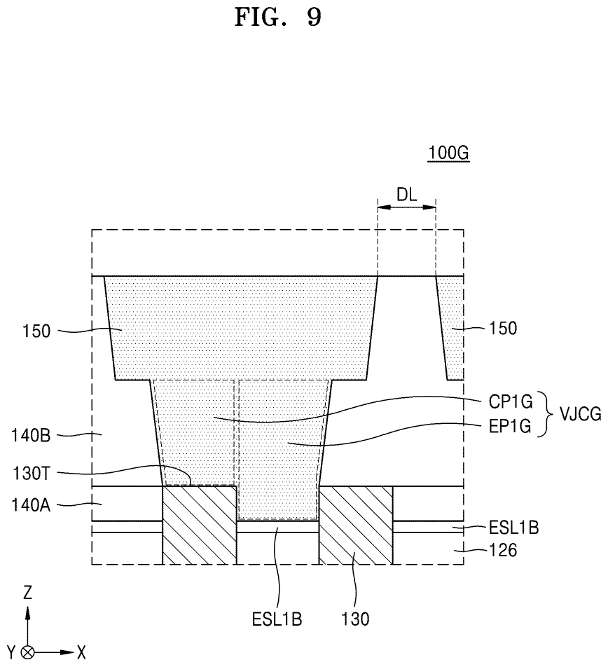

Referring to FIG. 9, the integrated circuit device 100G has substantially the same configuration as the integrated circuit device 100F described with reference to FIG. 8. However, the integrated circuit device 100G includes a via jumper contact unit VJCG that is connected to a pair of lower metal wiring layers 130 adjacent to each other from among the plurality of lower metal wiring layers 130. One upper metal wiring layer 150 from among the plurality of upper metal wiring layers 150 (see FIG. 1) may be integrally connected to the via jumper contact unit VJCG.

The via jumper contact unit VJCG may be in contact with one sidewall of one lower metal wiring layer 130 from the pair of lower metal wiring layers 130, the upper surface 130T, and one sidewall of the other lower metal wiring layer 130 from the pair of lower metal wiring layers 130, and the upper surface of the insulating etch stop layer ESL1B that is arranged between the pair of lower metal wiring layers 130 and covers the upper surface of the lower insulating film 126. More specifically, the via jumper contact unit VJCG may include a contact connection portion EP1G, which has a contact surface contacting one sidewall of the one lower metal wiring layer 130 from the pair of lower metal wiring layers 130 adjacent to each other, a contact surface contacting one sidewall of the other lower metal wiring layer 130 from the pair of lower metal wiring layers 130, and a contact surface contacting the upper surface of the insulating etch stop layer ESL1B arranged between the pair of lower metal wiring layers 130 to cover the lower insulating film 126. The via jumper contact unit VJCG may further include a contact portion CP1G, which is integrally connected to the contact connection portion EP1G and has a contact surface contacting the upper surface 130T of the other lower metal wiring layer 130 from the pair of lower metal wiring layers 130. The via jumper contact unit VJCG may not be in contact with the upper surface 130T of the one lower metal wiring layer 130 from the pair of lower metal wiring layers 130.

According to the integrated circuit device 100G shown in FIG. 9, the width of the via jumper contact unit VJCG in the first horizontal direction (the X direction) may be reduced such that the via jumper contact unit VJCG is not in contact with the upper surface 130T of the one lower metal wiring layer 130 from the pair of lower metal wiring layers 130, and the width, in the first horizontal direction (the X direction), of the upper metal wiring layer 150 integrally connected to the via jumper contact unit VJCG may also be reduced. Therefore, a separation distance DL between the upper metal wiring layer 150 integrally connected to the via jumper contact unit VJCG and another upper metal wiring layer 150 adjacent to the upper metal wiring layer 150 may be easily secured.

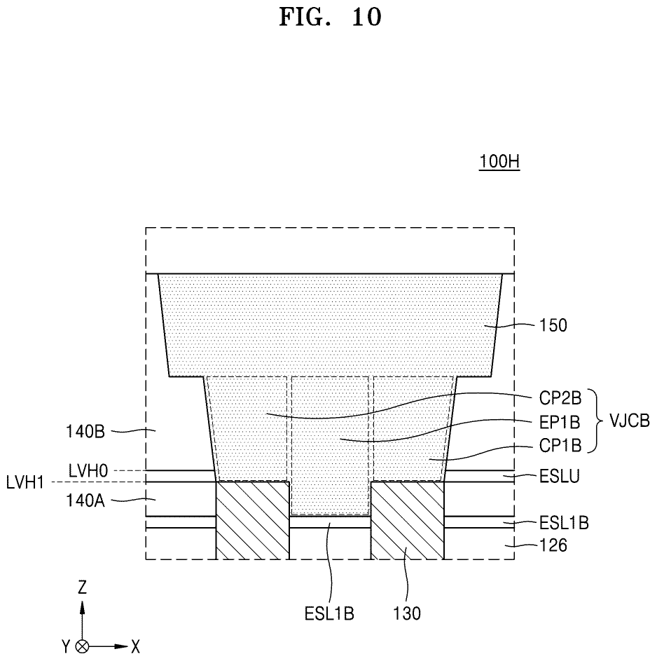

Referring to FIG. 10, the integrated circuit device 100H has substantially the same configuration as the integrated circuit device 100F described with reference to FIG. 8. However, the integrated circuit device 100H further includes an upper insulating etch stop layer ESLU between the first upper insulating film 140A and the second upper insulating film 140B.

The lower surface of the upper insulating etch stop layer ESLU may be in contact with the upper surface of the first upper insulating film 140A, and the upper surface of the upper insulating etch stop layer ESLU may be in contact with the lower surface of the second upper insulating film 140B. A vertical level LVH0 of the upper surface of the upper insulating etch stop layer ESLU may be higher than the vertical level LVH1 of the uppermost surface of each of the plurality of lower metal wiring layers 130. The upper insulating etch stop layer ESLU may be in contact with the sidewall of the via jumper contact unit VJCB.

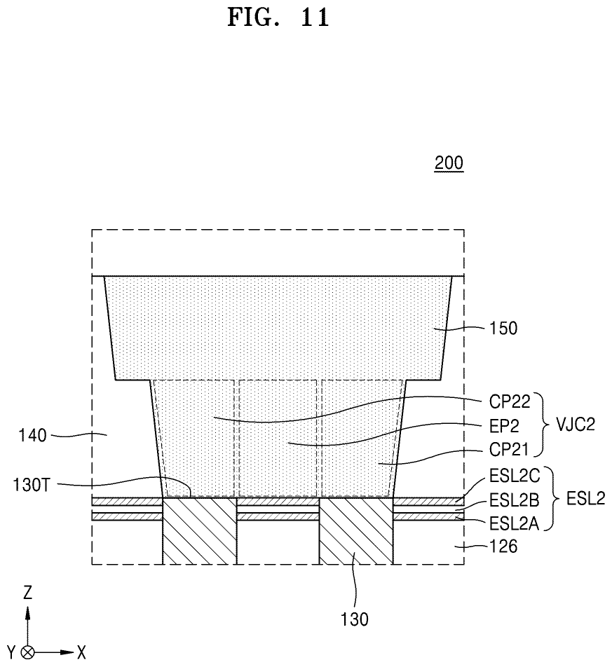

Referring to FIG. 11, the integrated circuit device 200 has substantially the same configuration as the integrated circuit device 100A described with reference to FIG. 3. However, the integrated circuit device 200 includes an insulating etch stop layer ESL2, which has a multilayer structure, and a via jumper contact unit VJC2, which is arranged on the insulating etch stop layer ESL2 and connected to a pair of lower metal wiring layers 130 adjacent to each other from among the plurality of lower metal wiring layers 130. One upper metal wiring layer 150 from among the plurality of upper metal wiring layers 150 (see FIG. 1) may be integrally connected to the via jumper contact unit VJC2.

The via jumper contact unit VJC2 may be in contact with the upper surface 130T of each of the pair of lower metal wiring layers 130, which are adjacent to each other, and the upper surface of the insulating etch stop layer ESL2 that is arranged between the pair of lower metal wiring layers 130 and covers the upper surface of the lower insulating film 126. The via jumper contact unit VJC2 may include a first contact portion CP21 contacting the upper surface 130T of one lower metal wiring layer 130 from the pair of lower metal wiring layers 130 adjacent to each other, a second contact portion CP22 contacting the upper surface 130T of the other lower metal wiring layer 130 from the pair of lower metal wiring layers 130, and a contact connection portion EP2 extending in the first horizontal direction (the X direction) between the first contact portion CP21 and the second contact portion CP22 and integrally connected to each of the first contact portion CP21 and the second contact portion CP22.

In the via jumper contact unit VJC2, the lower surface of the first contact portion CP21, the lower surface of the second contact portion CP22, and the lower surface of the contact connection portion EP2 may extend in the horizontal direction (the X direction and the Y direction). The lower surface of the first contact portion CP21, the lower surface of the second contact portion CP22, and the lower surface of the contact connection portion EP2 are at the same or similar vertical levels. In the via jumper contact unit VJC2, a vertical level of a contact surface, which contacts the insulating etch stop layer ESL2, of the contact connection portion EP2, a vertical level of a contact surface, which contacts the upper surface 130T of the lower metal wiring layer 130, of the first contact portion CP21, and a vertical level of a contact surface, which contacts the upper surface 130T of the lower metal wiring layer 130, of the second contact portion CP22 may be equal to or similar to each other. More detailed configurations of the first contact portion CP21, the second contact portion CP22, and the contact connection portion EP2 are respectively and substantially the same as those of the first contact portion CP1, the second contact portion CP2, and the contact connection portion EP1, which are described with reference to FIGS. 2A and 2C.

In the integrated circuit device 200, the insulating etch stop layer ESL2 may cover the upper surface of the lower insulating film 126 and the sidewall of each of the pair of lower metal wiring layers 130 connected to the via jumper contact unit VJC2. The insulating etch stop layer ESL2 may not include a portion covering the upper surface of each of the plurality of lower metal wiring layers 130. The contact connection portion EP2 of the via jumper contact unit VJC2 may be in contact with the upper surface of the insulating etch stop layer ESL2 while located to overlap (e.g., arranged over), in the vertical direction (the Z direction), a local region of the lower insulating film 126 that is arranged between the pair of lower metal wiring layers 130 connected to the via jumper contact unit VJC2.

The insulating etch stop layer ESL2 may include at least two different material films. As shown in FIG. 11, the insulating etch stop layer ESL2 may have a triple-layer structure in which a first insulating layer ESL2A, a second insulating layer ESL2B, and a third insulating layer ESL2C are sequentially stacked in the stated order. In some implementations, each of the first insulating layer ESL2A and the third insulating layer ESL2C may include a silicon nitride film, and the second insulating layer ESL2B may include a silicon oxide film. The lower surface of the contact connection portion EP2 of the via jumper contact unit VJC2 may be in contact with the upper surface of the third insulating layer ESL2C of the insulating etch stop layer ESL2.

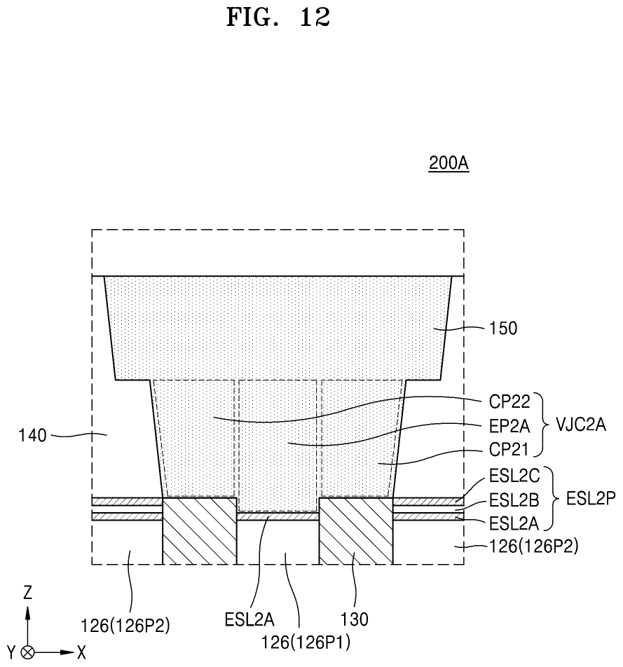

Referring to FIG. 12, the integrated circuit device 200A has substantially the same configuration as the integrated circuit device 200 described with reference to FIG. 11. However, the integrated circuit device 200A includes an insulating etch stop layer ESL2P, which has a multilayer structure, and a via jumper contact unit VJC2A, which is arranged on the insulating etch stop layer ESL2P and connected to a pair of lower metal wiring layers 130 adjacent to each other from among the plurality of lower metal wiring layers 130. One upper metal wiring layer 150 from among the plurality of upper metal wiring layers 150 (see FIG. 1) may be integrally connected to the via jumper contact unit VJC2A.

The insulating etch stop layer ESL2P may have different structures and thicknesses in the vertical direction (the Z direction), depending on positions therein. The lower insulating film 126 may include a local region 126P1, which is arranged between the pair of lower metal wiring layers 130 connected to the via jumper contact unit VJC2A, and a peripheral local region 126P2, which is spaced apart from the local region 126P1 in the first horizontal direction (the X direction) with the lower metal wiring layer 130 therebetween. A portion of the insulating etch stop layer ESL2P, which covers the local region 126P1 of the lower insulating film 126, and a portion of the insulating etch stop layer ESL2P, which covers the peripheral local region 126P2 of the lower insulating film 126, may have different thicknesses and different structures.

The portion of the insulating etch stop layer ESL2P, which covers the local region 126P1 of the lower insulating film 126, may have a thickness that is less than that of the portion of the insulating etch stop layer ESL2P, which covers the peripheral local region 126P2 of the lower insulating film 126. The portion of the insulating etch stop layer ESL2P, which covers the peripheral local region 126P2 of the lower insulating film 126, may have a triple-layer structure in which the first insulating layer ESL2A, the second insulating layer ESL2B, and the third insulating layer ESL2C are sequentially stacked in the stated order, as described regarding the insulating etch stop layer ESL2 with reference to FIG. 11. The portion of the insulating etch stop layer ESL2P, which covers the local region 126P1 of the lower insulating film 126, may have a single-layer structure including the first insulating layer ESL2A. In some implementations, each of the first insulating layer ESL2A and the third insulating layer ESL2C of the insulating etch stop layer ESL2P may include a silicon nitride film, and the second insulating layer ESL2B of the insulating etch stop layer ESL2P may include a silicon oxide film.

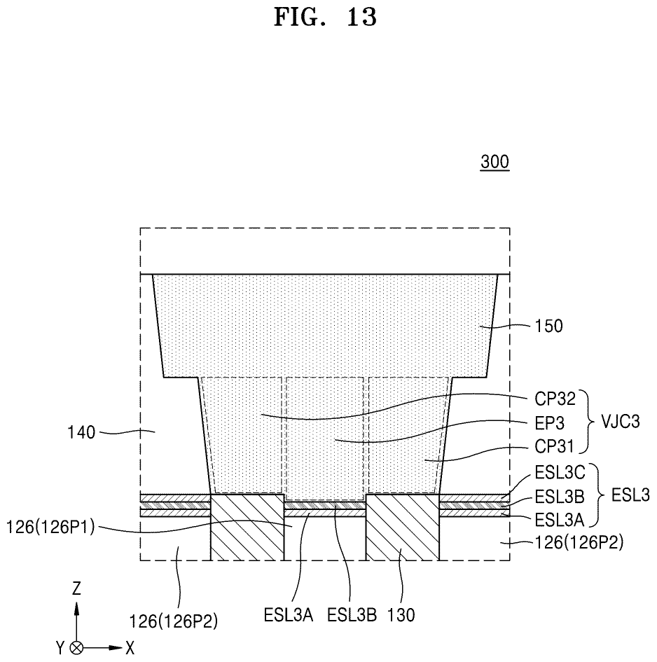

Referring to FIG. 13, the integrated circuit device 300 has substantially the same configuration as the integrated circuit device 200 described with reference to FIG. 11. However, the integrated circuit device 300 includes an insulating etch stop layer ESL3, which has a multilayer structure, and a via jumper contact unit VJC3, which is arranged on the insulating etch stop layer ESL3 and connected to a pair of lower metal wiring layers 130 adjacent to each other from among the plurality of lower metal wiring layers 130. One upper metal wiring layer 150 from among the plurality of upper metal wiring layers 150 (see FIG. 1) may be integrally connected to the via jumper contact unit VJC3.

The insulating etch stop layer ESL3 may have different structures and thicknesses in the vertical direction (the Z direction), depending on positions therein. The lower insulating film 126 may include a local region 126P1, which is arranged between the pair of lower metal wiring layers 130 connected to the via jumper contact unit VJC3, and a peripheral local region 126P2, which is spaced apart from the local region 126P1 in the first horizontal direction (the X direction) with the lower metal wiring layer 130 therebetween. A portion of the insulating etch stop layer ESL3, which covers the local region 126P1 of the lower insulating film 126, and a portion of the insulating etch stop layer ESL3, which covers the peripheral local region 126P2 of the lower insulating film 126, may have different thicknesses and different structures.

The portion of the insulating etch stop layer ESL3, which covers the local region 126P1 of the lower insulating film 126, may have a thickness that is less than that of the portion of the insulating etch stop layer ESL3, which covers the peripheral local region 126P2 of the lower insulating film 126. The portion of the insulating etch stop layer ESL3, which covers the peripheral local region 126P2 of the lower insulating film 126, may have a triple-layer structure in which a first insulating layer ESL3A, a second insulating layer ESL3B, and a third insulating layer ESL3C are sequentially stacked in the stated order. The portion of the insulating etch stop layer ESL3, which covers the local region 126P1 of the lower insulating film 126, may have a double-layer structure including the first insulating layer ESL3A and the second insulating layer ESL3B. The first insulating layer ESL3A and the second insulating layer ESL3B may respectively include different materials. In some implementations, each of the first insulating layer ESL3A and the third insulating layer ESL3C of the insulating etch stop layer ESL3 may include a silicon oxide film, and the second insulating layer ESL3B of the insulating etch stop layer ESL3 may include a silicon nitride film.

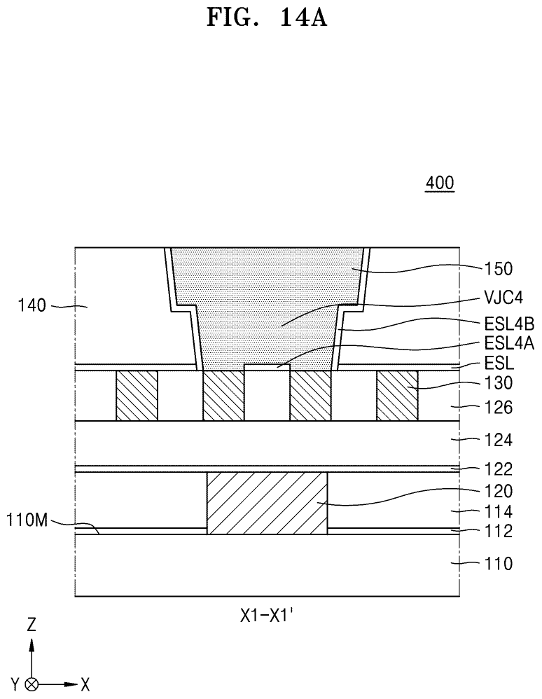

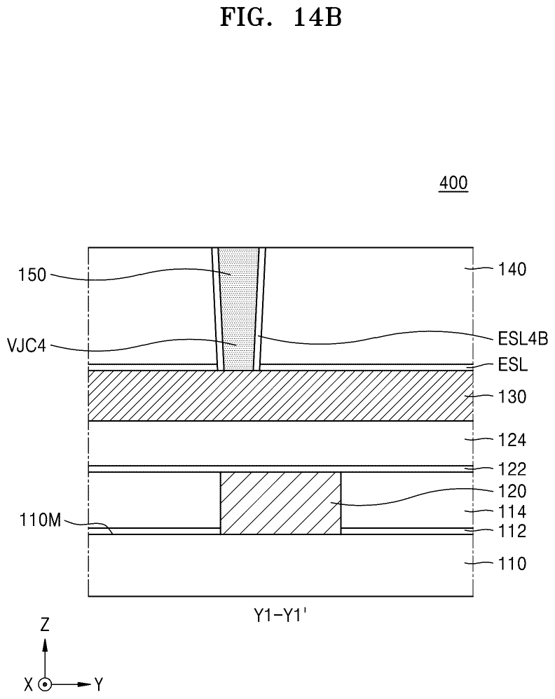

FIGS. 14A and 14B are cross-sectional views illustrating an integrated circuit device 400 according to some implementations. FIG. 14A illustrates a cross-sectional configuration of a portion of the integrated circuit device 400, the portion corresponding to a cross-section taken along the line X1-X1′ of FIG. 1, and FIG. 14B illustrates a cross-sectional configuration of a portion of the integrated circuit device 400, the portion corresponding to a cross-section taken along the line Y1-Y1′ of FIG. 1. In FIGS. 14A and 14B, the same reference numerals as in FIGS. 1 and 2A to 2C respectively denote the same members, and here, repeated descriptions thereof are omitted.

Referring to FIGS. 14A and 14B, the integrated circuit device 400 has substantially the same configuration as the integrated circuit device 100 described with reference to FIGS. 1 and 2A to 2C. However, the integrated circuit device 400 includes a via jumper contact unit VJC4, an insulating etch stop layer ESL4A, an insulating liner ESL4B, and a base etch stop layer ESL.

The via jumper contact unit VJC4 may be connected to a pair of lower metal wiring layers 130 adjacent to each other from among the plurality of lower metal wiring layers 130. A more detailed configuration of the via jumper contact unit VJC4 is substantially the same as that of the via jumper contact unit VJC described with reference to FIGS. 2A to 2C.

The insulating etch stop layer ESL4A may cover a local region of the lower insulating film 126, which is arranged between the pair of lower metal wiring layers 130, and may be arranged between the pair of lower metal wiring layers 130 to contact the lower surface of the via jumper contact unit VJC4. A more detailed configuration of the insulating etch stop layer ESL4A is substantially the same as that of the insulating etch stop layer ESL1 described with reference to FIGS. 2A to 2C.

The insulating liner ESL4B may be arranged between the via jumper contact unit VJC4 and the upper insulating film 140 and between the upper metal wiring layer 150, which is integrally connected to the via jumper contact unit VJC4, and the upper insulating film 140 and may be in contact with each of the via jumper contact unit VJC4, the upper metal wiring layer 150, and the upper insulating film 140. The insulating liner ESL4B and the insulating etch stop layer ESL4A may include the same material. In some implementations, each of the insulating liner ESL4B and the insulating etch stop layer ESL4A may include, but is not limited to, a silicon nitride film.

The base etch stop layer ESL may cover portions of both the upper surface of the lower insulating film 126 and the upper surfaces of the plurality of lower metal wiring layers 130 except for the upper surface of each of the pair of lower metal wiring layers 130, which are connected to the via jumper contact unit VJC4, and the upper surface of the local region of the lower insulating film 126, which is arranged between the pair of lower metal wiring layers 130. The insulating liner ESL4B may include a portion between the base etch stop layer ESL and the via jumper contact unit VJC4. The base etch stop layer ESL may be spaced apart from the via jumper contact unit VJC4 with the insulating liner ESL4B therebetween. A constituent material of the base etch stop layer ESL is the same as described regarding the constituent material of each of the first lower etch stop layer 112 and the second lower etch stop layer 122 with reference to FIGS. 2A and 2B.

According to the integrated circuit devices described with reference to FIGS. 3 to 13 and FIGS. 14A and 14B, similar to the integrated circuit device 100 described with reference to FIGS. 1 and 2A to 2C, each of the integrated circuit devices includes a via jumper contact unit connected to at least two lower metal wiring layers that are selected from a plurality of lower metal wiring layers passing through a lower insulating film in the vertical direction, and an insulating etch stop layer arranged between the lower insulating film and the lower surface of a contact connection portion of the via jumper contact unit, the contact connection portion overlapping the lower insulating film in the vertical direction. A local region of the lower insulating film, which is arranged between the at least two lower metal wiring layers connected to the via jumper contact unit, is covered by the insulating etch stop layer, when an etching process for preparing a space, in which the via jumper contact unit is to be located, is performed in a fabrication process of an integrated circuit device. Accordingly, the lower insulating film between the at least two lower metal wiring layers may be prevented from being unintentionally consumed and recessed. In addition, a vertical level of the lower surface of the contact connection portion of the via jumper contact unit may be stably controlled by the insulating etch stop layer contacting the lower surface of the contact connection portion, and thus, the possibility of an unintended short-circuit between the via jumper contact unit and another conductive component that is at a lower vertical level than the plurality of lower metal wiring layers may be suppressed. Therefore, the productivity and reliability of the integrated circuit device may improve.

Next, a method of fabricating integrated circuit devices, according to implementations, is described by taking a specific example.

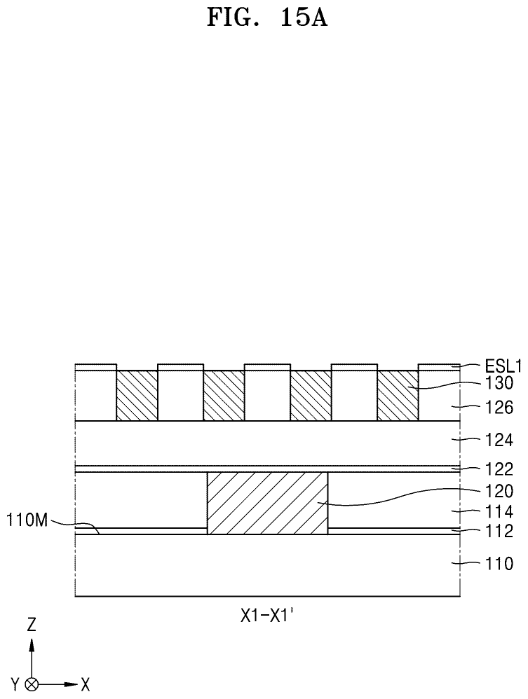

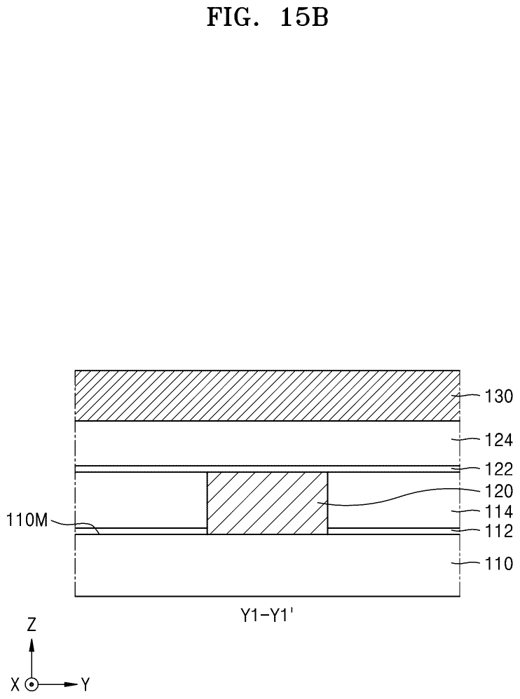

FIGS. 15A to 21B are cross-sectional views respectively illustrating a sequence of processes of a method of fabricating an integrated circuit device, according to implementations, and in particular, FIGS. 15A, 16A, 17A, 18A, 19A, 20A, and 21A are cross-sectional views of a region corresponding to the cross-section taken along the line X1-X1′ of FIG. 1, according to the sequence of processes, and FIGS. 15B, 16B, 17B, 18B, 19B, 20B, and 21B are cross-sectional views of a region corresponding to the cross-section taken along the line Y1-Y1′ of FIG. 1, according to the sequence of processes. An example of a method of fabricating the integrated circuit device 100 shown in FIGS. 1 and 2A to 2C is described with reference to FIGS. 15A to 21B. In FIGS. 15A to 21B, the same reference numerals as in FIGS. 1 and 2A to 2C respectively denote the same members, and here, repeated descriptions thereof are omitted.

Referring to FIGS. 15A and 15B, a first lower etch stop layer 112 and a first interlayer dielectric 114 may be formed on the main surface 110M of the substrate 110, and a conductive structure 120 may be formed through the first interlayer dielectric 114 and the first lower etch stop layer 112 so as to be electrically connected to a conductive region (not shown) of the substrate 110. To form the conductive structure 120, an opening may be formed by partially etching the first interlayer dielectric 114 and the first lower etch stop layer 112, and then, conductive materials may fill the opening. The conductive structure 120 may be electrically connected to the conductive region formed in the substrate 110. In some implementations, to form the conductive structure 120, a source/drain region of a transistor, a source/drain contact, a via contact, or a gate contact may be formed, but the disclosure is not limited thereto.

A second lower etch stop layer 122 and a second interlayer dielectric 124 may be formed on or over the first interlayer dielectric 114. Next, a lower insulating film 126 may be formed on the second interlayer dielectric 124, and a plurality of lower metal wiring layers 130 may be formed to pass through the lower insulating film 126 in the vertical direction (the Z direction).

Next, an insulating etch stop layer ESL1 may be selectively formed on only the upper surface of the lower insulating film 126 from among the exposed upper surface of the lower insulating film 126 and the respective exposed upper surfaces of the plurality of lower metal wiring layers 130. To selectively form the insulating etch stop layer ESL1 on only the upper surface of the lower insulating film 126, a selective growth process well known in the art may be used.

In some implementations, to selectively form the insulating etch stop layer ESL1 on only the upper surface of the lower insulating film 126 from among the exposed upper surface of the lower insulating film 126 and the respective exposed upper surfaces of the plurality of lower metal wiring layers 130, a blocking layer may be formed first to selectively cover the respective upper surfaces of the plurality of lower metal wiring layers 130, and here, the blocking layer may include a self-assembled monolayer. The self-assembled monolayer may be bonded to the upper surface of each of the plurality of lower metal wiring layers 130 by using at least one anchor group. The anchor group may include, but is not limited to, phosphorous, sulfur, silicon, carbon, or nitrogen. In some implementations, the blocking layer may include, but is not limited to, an organic material, such as benzotriazole. In some implementations, to form the blocking layer, an atomic layer deposition (ALD) process, a chemical vapor deposition (CVD) process, a spin-coating process, or a dipping process may be used.

After the blocking layer is formed, the upper surface of the lower insulating film 126 may be exposed by the blocking layer. Next, the insulating etch stop layer ESL1 may be selectively formed on only the upper surface of the lower insulating film 126, which is exposed by the blocking layer, by using a selective deposition process. In some implementations, to form the insulating etch stop layer ESL1 by using the selective deposition process, a CVD process or an ALD process may be used. After the insulating etch stop layer ESL1 is formed, the upper surface of each of the plurality of lower metal wiring layers 130 may be exposed by removing the blocking layer.

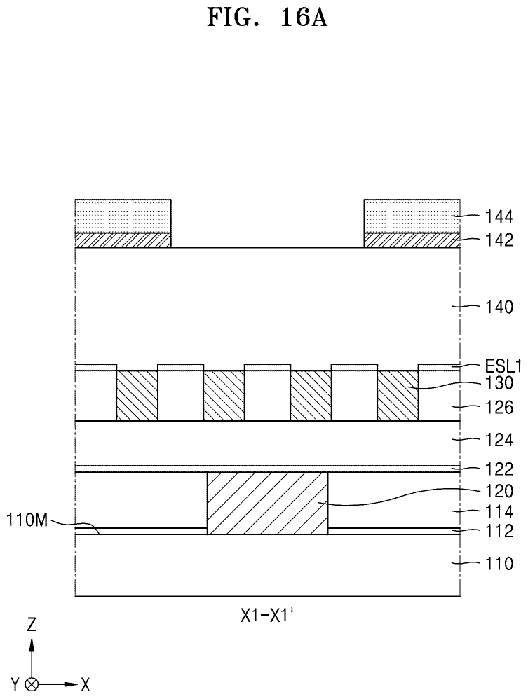

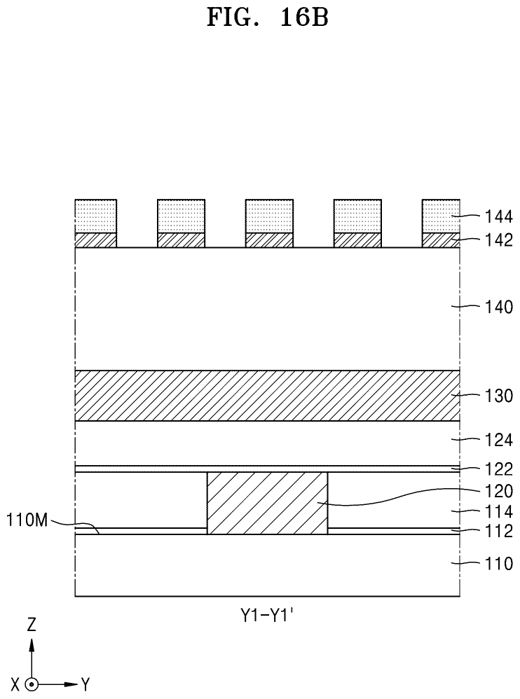

Referring to FIGS. 16A and 16B, an upper insulating film 140 may be formed on the resulting product of FIGS. 15A and 15B, and a stack structure of a first mask pattern 142 and a second mask pattern 144 may be formed on the upper insulating film 140. A portion of the upper surface of the upper insulating film 140 may be exposed by the stack structure of the first mask pattern 142 and the second mask pattern 144. The first mask pattern 142 and the second mask pattern 144 may respectively include materials having different etch selectivities. In some implementations, the first mask pattern 142 may include TiN and the second mask pattern 144 may include SiON, but the disclosure is not limited thereto.

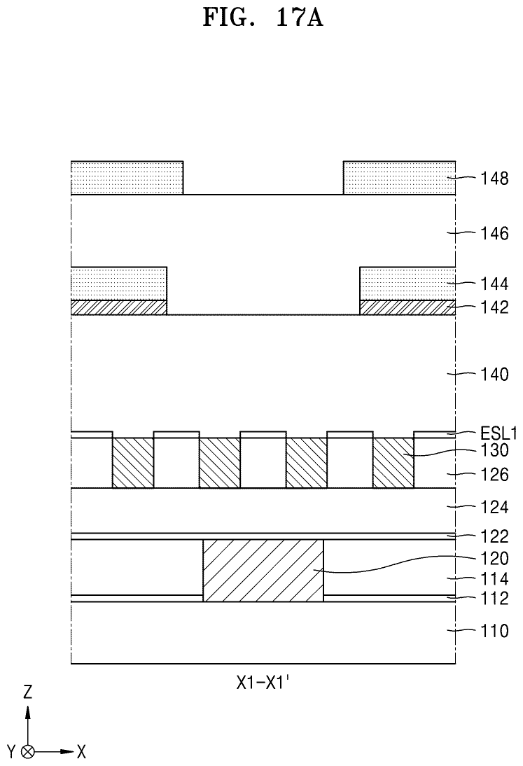

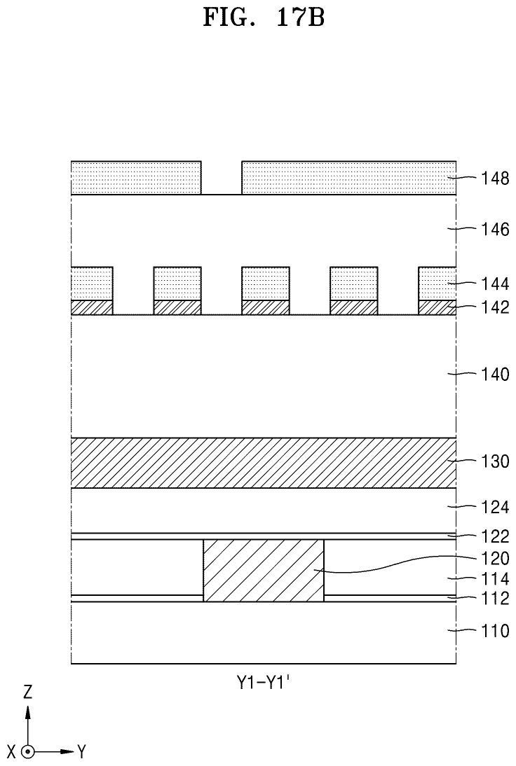

Referring to FIGS. 17A and 17B, a third mask layer 146 may be formed on the resulting product of FIGS. 16A and 16B, and a fourth mask pattern 148 may be formed on the third mask layer 146. A portion of the upper surface of the third mask layer 146 may be exposed by the fourth mask pattern 148. The third mask layer 146 and the fourth mask pattern 148 may respectively include materials having different etch selectivities. In some implementations, the third mask layer 146 may include a spin-on-hardmask (SOH) and the fourth mask pattern 148 may include SiON, but the disclosure is not limited thereto.

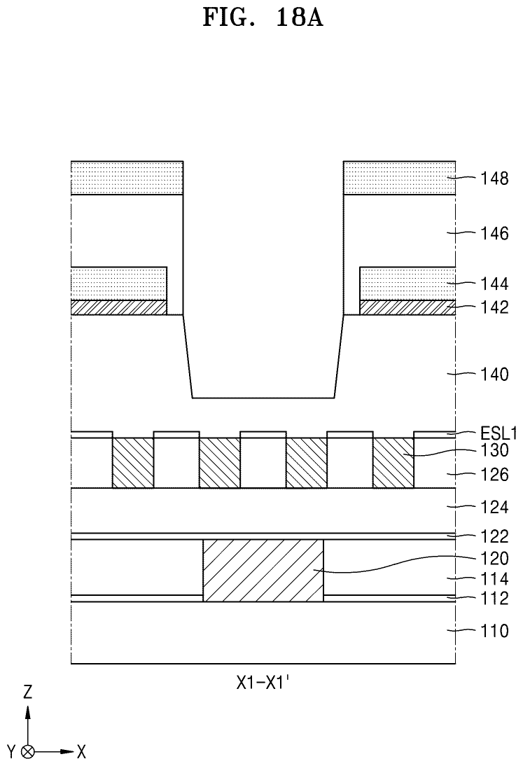

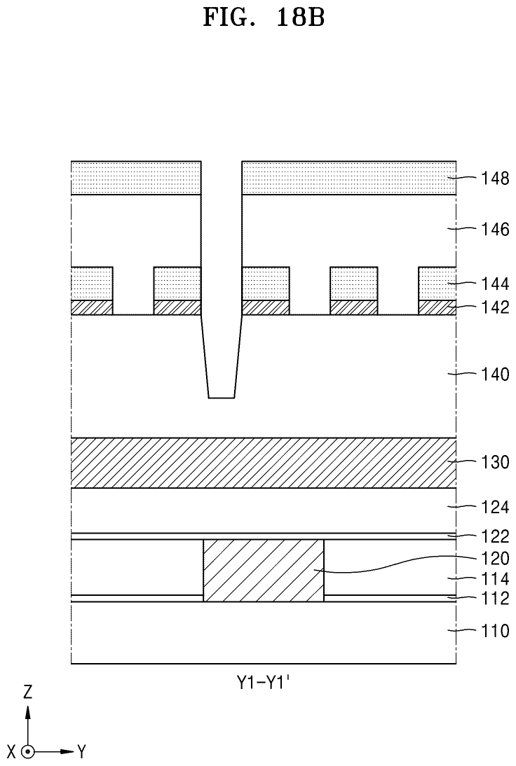

Referring to FIGS. 18A and 18B, in the resulting product of FIGS. 17A and 17B, the third mask layer 146 may be etched by using the fourth mask pattern 148 as an etch mask, thereby exposing the upper insulating film 140, and then, the upper insulating film 140 under the third mask layer 146 may be removed by a certain thickness.

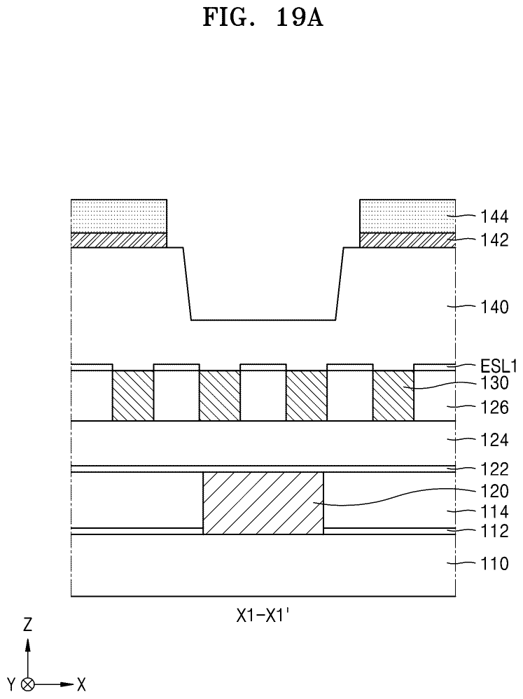

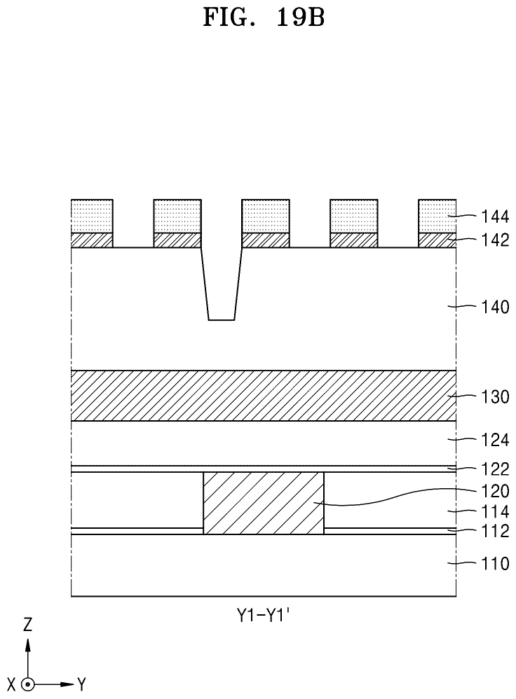

Referring to FIGS. 19A and 19B, the third mask layer 146 and the fourth mask pattern 148, which remain in the resulting product of FIGS. 18A and 18B, may be removed, thereby exposing the upper surface of the second mask pattern 144 and exposing the upper surface of the upper insulating film 140 around the stack structure of the first mask pattern 142 and the second mask pattern 144.

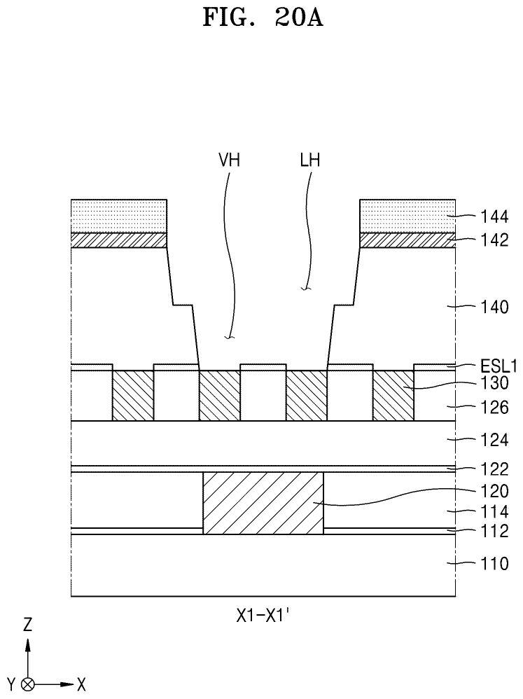

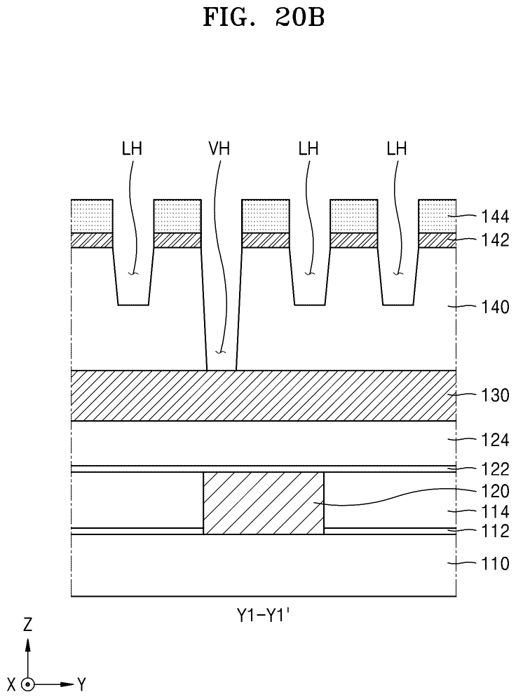

Referring to FIGS. 20A and 20B, in the resulting product of FIGS. 19A and 19B, the upper insulating film 140, which is exposed by the stack structure of the first mask pattern 142 and the second mask pattern 144, may be etched by using the stack structure as an etch mask, thereby forming a plurality of upper wiring trenches LH and a via hole VH. The plurality of upper wiring trenches LH may include an upper wiring trench LH connected to the via hole VH.

The upper surface of each of a pair of lower metal wiring layers 130, to which a via jumper contact unit VJC (see FIGS. 1 and 2A to 2C) is to be connected, from among the plurality of lower metal wiring layers 130 and a portion of the insulating etch stop layer ESL1, which is between the pair of lower metal wiring layers 130, may be exposed through the via hole VH.

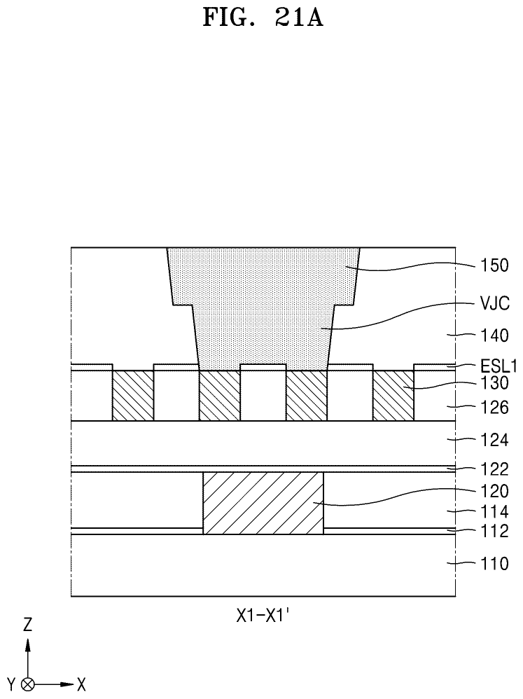

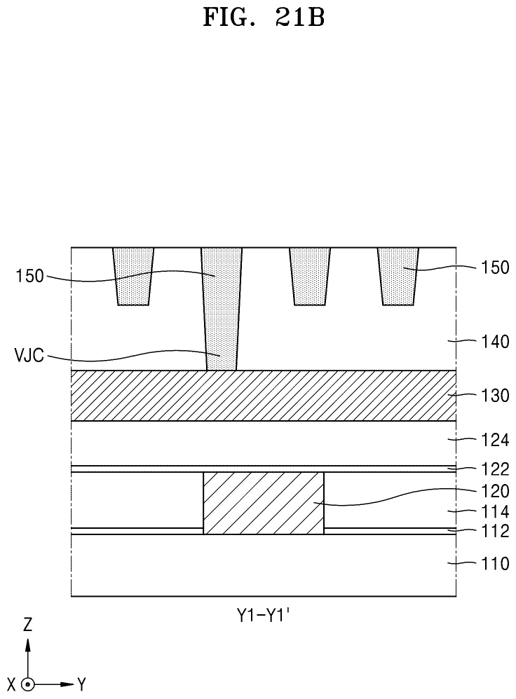

Referring to FIGS. 21A and 21B, in the resulting product of FIGS. 20A and 20B, a conductive layer may be formed to fill the plurality of upper wiring trenches LH and the via hole VH, followed by planarizing the conductive layer such that the upper surface of the upper insulating film 140 is exposed, thereby forming a plurality of upper metal wiring layers 150 and the via jumper contact unit VJC to respectively fill the plurality of upper wiring trenches LH and the via hole VH. The plurality of upper metal wiring layers 150 may include an upper metal wiring layer 150 integrally connected to the via jumper contact unit VJC.

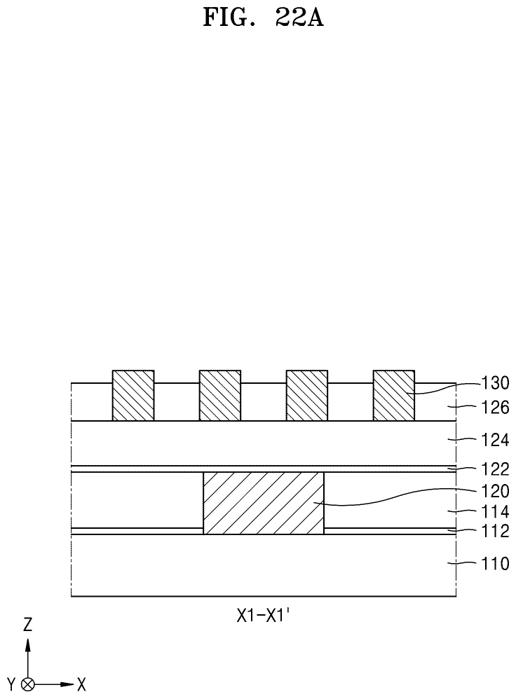

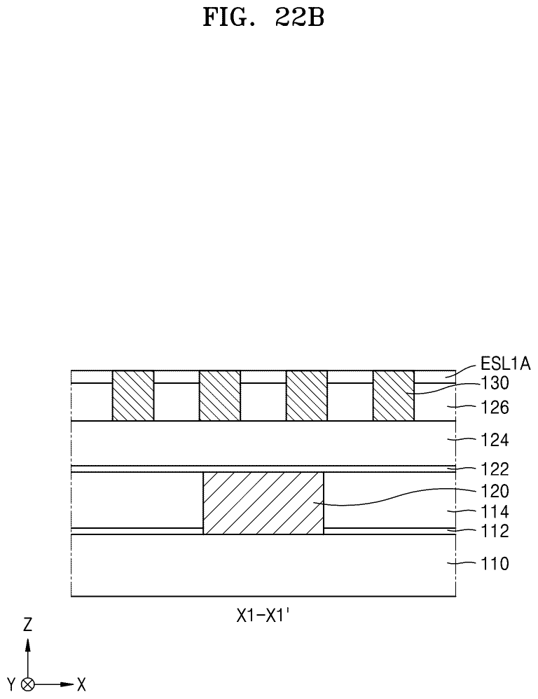

FIGS. 22A and 22B are cross-sectional views respectively illustrating a sequence of processes of a method of fabricating an integrated circuit device, according to some implementations. FIGS. 22A and 22B respectively illustrate cross-sectional configurations of a region corresponding to the cross-section taken along the line X1-X1′ of FIG. 1, according to the sequence of processes. An example of a method of fabricating the integrated circuit device 100A shown in FIG. 3 is described with reference to FIGS. 22A and 22B. In FIGS. 22A and 22B, the same reference numerals as in FIGS. 1 to 21B respectively denote the same members, and here, repeated descriptions thereof are omitted.

Referring to FIG. 22A, as described with reference to FIGS. 15A and 15B, the process may be performed up to forming the plurality of lower metal wiring layers 130 to pass through the lower insulating film 126 in the vertical direction (the Z direction). After the plurality of lower metal wiring layers 130 are formed, a resulting product having a flat upper surface such that the respective upper surfaces of the lower insulating film 126 and the plurality of lower metal wiring layers 130 extend in the same plane may be obtained. An etch-back process is performed on the resulting product having the flat upper surface, to remove the lower insulating film 126 from the exposed surface thereof by a certain thickness. Accordingly, a vertical level of the upper surface of the lower insulating film 126 is lower than a vertical level of the upper surface of each of the plurality of lower metal wiring layers 130, thereby causing an upper portion of each of the plurality of lower metal wiring layers 130 to protrude above the lowered upper surface of the lower insulating film 126.

Referring to FIG. 22B, in the resulting product of FIG. 22A, an insulating etch stop layer ESL1A may be selectively formed on only the upper surface of the lower insulating film 126 from among the exposed upper surface of the lower insulating film 126 and the respective exposed upper surfaces of the plurality of lower metal wiring layers 130. To selectively form the insulating etch stop layer ESL1A on only the upper surface of the lower insulating film 126, a selective growth process well known in the art may be used. For example, to form the insulating etch stop layer ESL1A, the processes described with reference to FIGS. 15A and 15B as examples of a process of forming the insulating etch stop layer ESL1 may be used. Next, the resulting product may undergo the processes described with reference to FIGS. 16A to 21B, thereby fabricating the integrated circuit device 100A shown in FIG. 3.

To fabricate the integrated circuit device 100B shown in FIG. 4, similar processes to the processes described with reference to FIGS. 22A and 22B may be performed. However, in the processes described with reference to FIG. 22A, when the etch-back process for removing the lower insulating film 126 from the exposed surface thereof by a certain thickness is performed such that the vertical level of the upper surface of the lower insulating film 126 is lower than the vertical level of the upper surface of each of the plurality of lower metal wiring layers 130. The thickness, by which the lower insulating film 126 is removed, may be increased, thereby causing the difference between the vertical level of the lowered upper surface of the lower insulating film 126 and the vertical level of the upper surface of each of the plurality of lower metal wiring layers 130 to be greater than that in the example shown in FIG. 22A. Next, the resulting product may undergo a similar process to the process described with reference to FIG. 22B, thereby selectively forming an insulating etch stop layer ESL1B on only the lowered upper surface of the lower insulating film 126. Next, the resulting product may undergo the processes described with reference to FIGS. 16A to 21B, thereby fabricating the integrated circuit device 100B shown in FIG. 4.

To fabricate each of the integrated circuit devices 100C, 100D, and 100E respectively shown in FIGS. 5, 6, and 7, similar processes to the processes described with reference to FIGS. 15A to 21B may be performed. However, in the processes described with reference to FIGS. 16A to 20B, the width of each of the via hole VH and the upper wiring trench LH connected thereto in the first horizontal direction (the X direction) may be variously modified according to the structure of the intended via jumper contact unit VJCC, VJCD, or VJCE.

To fabricate the integrated circuit device 100F shown in FIG. 8, similar processes to the processes of the method, described above, of fabricating the integrated circuit device 100B shown in FIG. 4 may be performed. However, after the insulating etch stop layer ESL1B is selectively formed on only the lowered upper surface of the lower insulating film 126, a first upper insulating film 140A and a second upper insulating film 140B, instead of the upper insulating film 140, may be sequentially formed in the stated order on the insulating etch stop layer ESL1B. Next, the resulting product may undergo the processes described with reference to FIGS. 16A to 21B, thereby fabricating the integrated circuit device 100F shown in FIG. 8.

To fabricate the integrated circuit device 100G shown in FIG. 9, similar processes to the processes of the method, described above, of fabricating the integrated circuit device 100F shown in FIG. 8 may be performed. However, in the processes described with reference to FIGS. 16A to 20B, some processes may be modified such that the width, in the first horizontal direction (the X direction), of each of the via hole VH and the upper wiring trench LH connected thereto is suited for the structure of the intended via jumper contact unit VJCG.

To fabricate the integrated circuit device 100H shown in FIG. 10, similar processes to the processes of the method, described above, of fabricating the integrated circuit device 100B shown in FIG. 4 may be performed. However, after the insulating etch stop layer ESL1B is selectively formed on only the lowered upper surface of the lower insulating film 126, a first upper insulating film 140A, an upper insulating etch stop layer ESLU, and a second upper insulating film 140B, instead of the upper insulating film 140, may be sequentially formed in the stated order on the insulating etch stop layer ESL1B. Next, the resulting product may undergo the processes described with reference to FIGS. 16A to 21B, thereby fabricating the integrated circuit device 100H shown in FIG. 10.

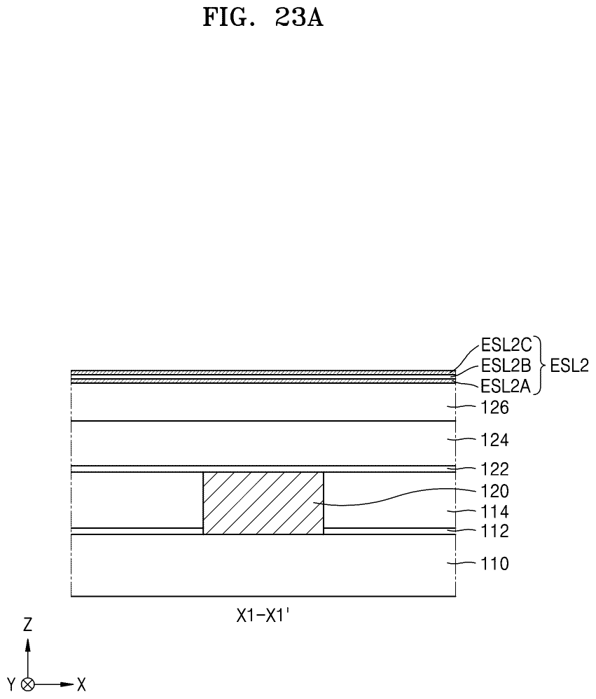

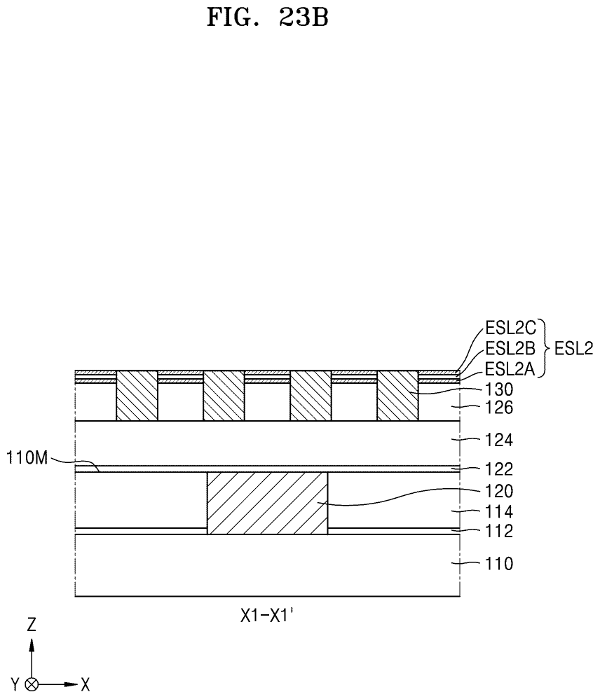

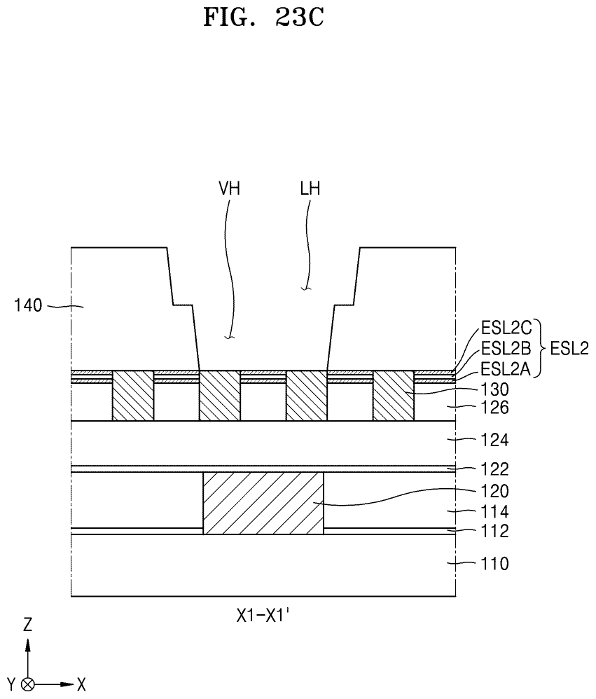

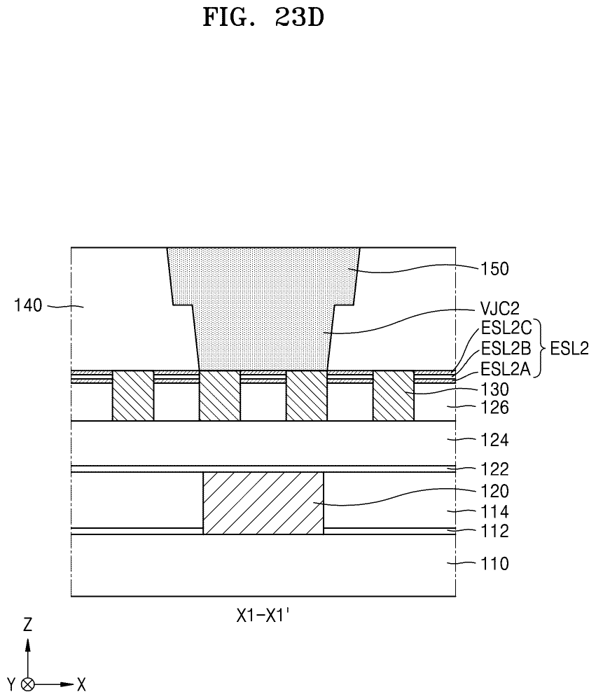

FIGS. 23A to 23D are cross-sectional views respectively illustrating a sequence of processes of a method of fabricating an integrated circuit device, according to some implementations. FIGS. 23A to 23D respectively illustrate cross-sectional configurations of a region corresponding to the cross-section taken along the line X1-X1′ of FIG. 1, according to the sequence of processes. An example of a method of fabricating the integrated circuit device 200 shown in FIG. 11 is described with reference to FIGS. 23A to 23D. In FIGS. 23A to 23D, the same reference numerals as in FIGS. 1 to 22B respectively denote the same members, and here, repeated descriptions thereof are omitted.

Referring to FIG. 23A, as described with reference to FIGS. 15A and 15B, the process may be performed up to forming the lower insulating film 126. Next, an insulating etch stop layer ESL2 may be formed on the lower insulating film 126, the insulating etch stop layer ESL2 having a triple-layer structure in which a first insulating layer ESL2A, a second insulating layer ESL2B, and a third insulating layer ESL2C are sequentially stacked in the stated order.

Referring to FIG. 23B, in the resulting product of FIG. 23A, a plurality of lower metal wiring layers 130 may be formed to pass through the insulating etch stop layer ESL2 and the lower insulating film 126 in the vertical direction (the Z direction).

Referring to FIG. 23C, the resulting product of FIG. 23B may undergo the processes described with reference to FIGS. 16A to 20B, thereby forming an upper wiring trench LH and a via hole VH to pass through the upper insulating film 140 in the vertical direction (the Z direction).

Referring to FIG. 23D, in the resulting product of FIG. 23C, an upper metal wiring layer 150, which fills the upper wiring trench LH, and a via jumper contact unit VJC2, which fills the via hole VH, may be formed by a similar process to the process described with reference to FIGS. 21A and 21B.

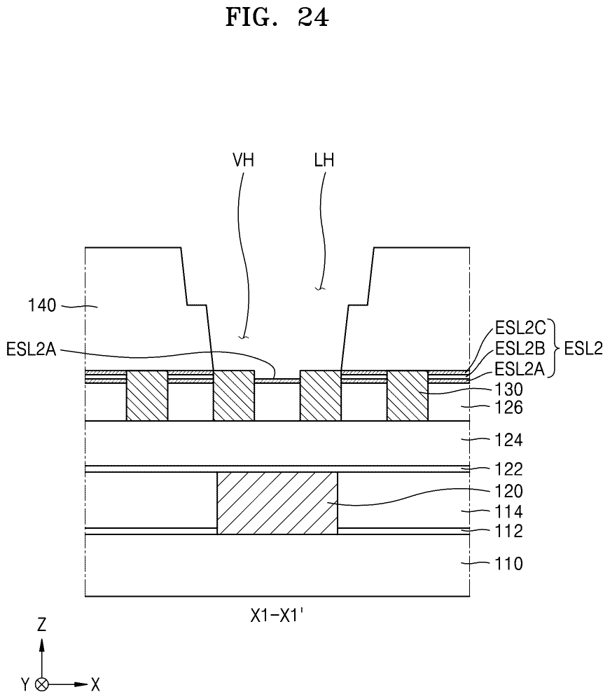

FIG. 24 is a cross-sectional view illustrating a method of fabricating an integrated circuit device, according to some implementations. FIG. 24 illustrates a cross-sectional configuration of a region corresponding to the cross-section taken along the line X1-X1′ of FIG. 1, according to a sequence of processes. An example of a method of fabricating the integrated circuit device 200A shown in FIG. 12 is described with reference to FIG. 24. In FIG. 24, the same reference numerals as in FIGS. 1 to 23D respectively denote the same members, and here, repeated descriptions thereof are omitted.

Referring to FIG. 24, to fabricate the integrated circuit device 200A, similar processes to the processes described with reference to FIGS. 23A to 23D may be performed. However, after the process of forming the upper wiring trench LH and the via hole VH to pass through the upper insulating film 140 in the vertical direction (the Z direction) is performed as described with reference to FIG. 23C, in the resulting product, the third insulating layer ESL2C, which is exposed through the upper wiring trench LH and the via hole VH, of the upper insulating etch stop layer ESL2 and the second insulating layer ESL2B under the third insulating layer ESL2C may be selectively removed, thereby exposing the first insulating layer ESL2A through the via hole VH. Next, an upper metal wiring layer 150, which fills the upper wiring trench LH, and a via jumper contact unit VJC2A, which fills the via hole VH, may be formed by a similar process to the process described with reference to FIGS. 21A and 21B.

To fabricate the integrated circuit device 300, similar processes to the processes of the method, described above, of fabricating the integrated circuit device 200 shown in FIG. 11 may be performed. However, in the process described with reference to FIG. 23A, instead of the insulating etch stop layer ESL2, an insulating etch stop layer ESL3 having a triple-layer structure, in which a first insulating layer ESL3A, a second insulating layer ESL3B, and a third insulating layer ESL3C are sequentially stacked in the stated order, may be formed. Next, similar to the description made with reference to FIG. 24, after the process of forming the upper wiring trench LH and the via hole VH to pass through the upper insulating film 140 in the vertical direction (the Z direction) is performed, in the resulting product, the third insulating layer ESL3C, which is exposed through the upper wiring trench LH and the via hole VH, of the upper insulating etch stop layer ESL3 may be selectively removed, thereby exposing the second insulating layer ESL3B through the via hole VH. Next, an upper metal wiring layer 150, which fills the upper wiring trench LH, and a via jumper contact unit VJC3, which fills the via hole VH, may be formed by a similar process to the process described with reference to FIGS. 21A and 21B.

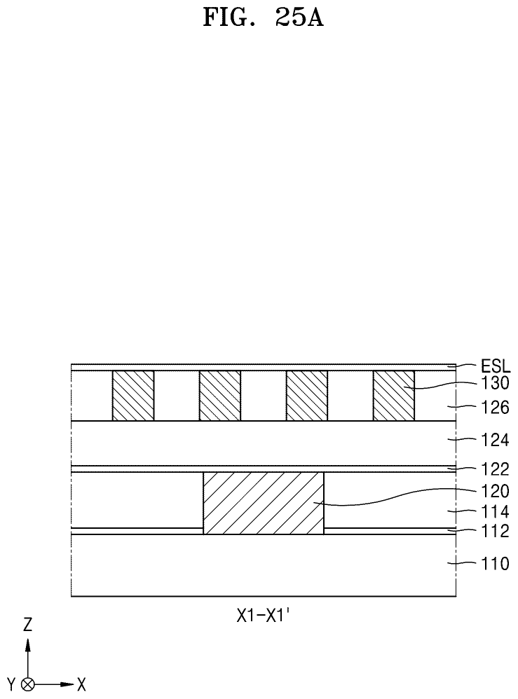

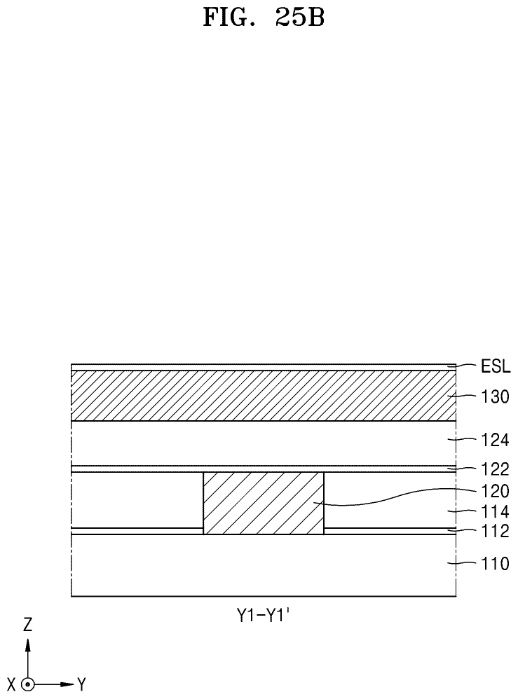

FIGS. 25A to 27B are cross-sectional views respectively illustrating a sequence of processes of a method of fabricating an integrated circuit device, according to some implementations, and in particular, FIGS. 25A, 26A, and 27A are cross-sectional views of a region corresponding to the cross-section taken along the line X1-X1′ of FIG. 1, according to the sequence of processes, and FIGS. 25B, 26B, and 27B are cross-sectional views of a region corresponding to the cross-section taken along the line Y1-Y1′ of FIG. 1, according to the sequence of processes. An example of a method of fabricating the integrated circuit device 400 shown in FIGS. 14A and 14B is described with reference to FIGS. 25A to 27B. In FIGS. 25A to 27B, the same reference numerals as in FIGS. 1 to 21B respectively denote the same members, and here, repeated descriptions thereof are omitted.

Referring to FIGS. 25A and 25B, as described with reference to FIGS. 15A and 15B, the process may be performed up to forming the plurality of lower metal wiring layers 130 to pass through the lower insulating film 126 in the vertical direction (the Z direction). After the plurality of lower metal wiring layers 130 are formed, a resulting product having a flat upper surface may be obtained such that the upper surface of the lower insulating film 126 and the respective upper surfaces of the plurality of lower metal wiring layers 130 extend in the same plane. Next, a base etch stop layer ESL may be formed to cover the upper surface of the lower insulating film 126 and the respective upper surfaces of the plurality of lower metal wiring layers 130.

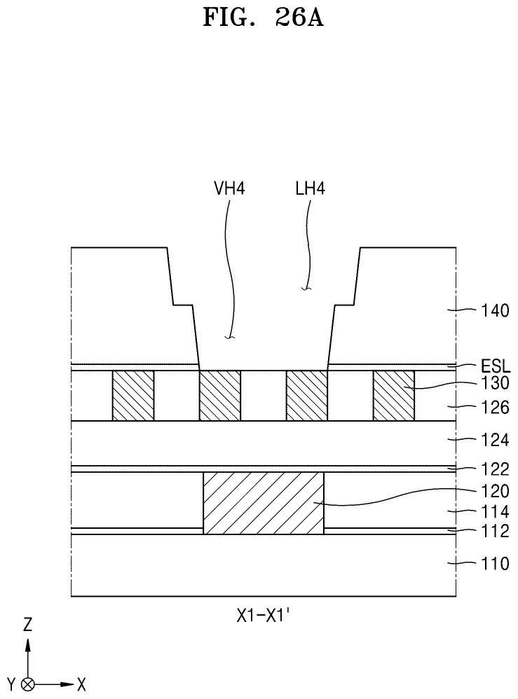

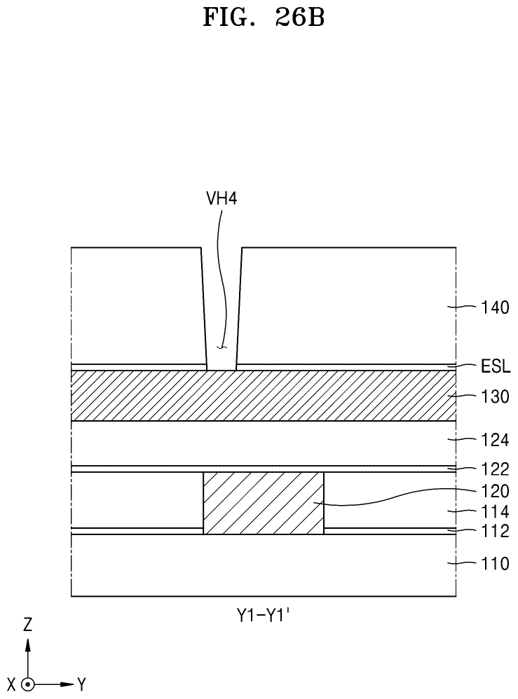

Referring to FIGS. 26A and 26B, the resulting product of FIGS. 25A and 25B may undergo the processes described with reference to FIGS. 16A to 20B, thereby forming an upper wiring trench LH4 and a via hole VH4 to pass through the upper insulating film 140 and the base etch stop layer ESL in the vertical direction (the Z direction). The upper surface of each of a pair of lower metal wiring layers 130, to which a via jumper contact unit VJC4 (see FIGS. 14A and 14B) is to be connected, from among the plurality of lower metal wiring layers 130 and a local region of the lower insulating film 126, which is between the pair of lower metal wiring layers 130, may be exposed through the via hole VH4.

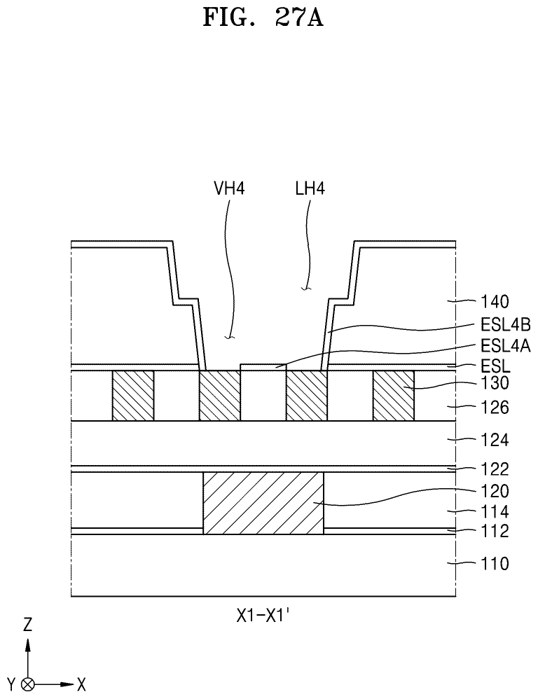

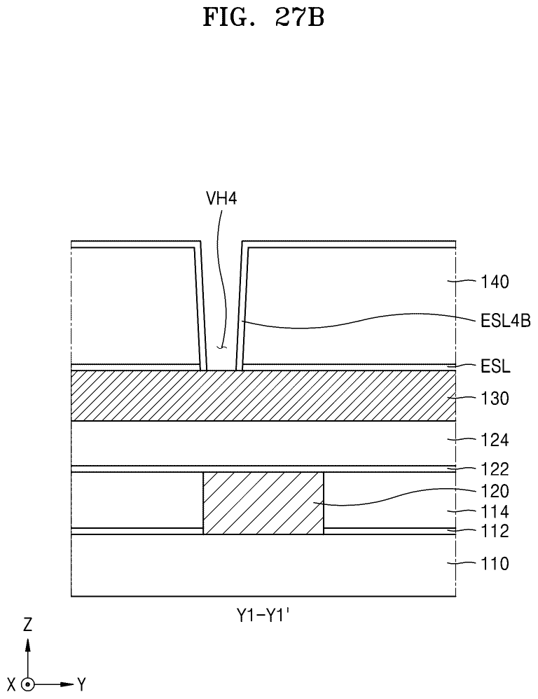

Referring to FIGS. 27A and 27B, in the resulting product of FIGS. 26A and 26B, a selective growth layer may be formed on only the upper surface of the lower insulating film 126 and the surfaces of the upper insulating film 140 from among the respective upper surfaces of the pair of lower metal wiring layers 130, the upper surface of the lower insulating film 126, and the surfaces of the upper insulating film 140. A portion of the selective growth layer, which covers the upper surface of the lower insulating film 126, may constitute an insulating etch stop layer ESL4A, and a portion of the selective growth layer, which covers the surfaces of the upper insulating film 140, may constitute an insulating liner ESL4B. To form the selective growth layer, a selective growth process well known in the art may be used. For example, to form the selective growth layer, the processes described with reference to FIGS. 15A and 15B as examples of a process of forming the insulating etch stop layer ESL1 may be used.

The resulting product of FIGS. 27A and 27B may undergo the processes described with reference to FIGS. 16A to 21B, thereby fabricating the integrated circuit device 400 shown in FIGS. 14A and 14B.

Heretofore, although the examples of the methods of fabricating the integrated circuit devices shown in FIGS. 1 to 14B have been described with reference to FIGS. 15A to 27B, it will be understood by those of ordinary skill in the art that, by making various modifications and changes to the examples described with reference to FIGS. 15A to 27B without departing from the spirit and scope of the disclosure, integrated circuit devices having various structures modified and changed from the integrated circuit devices shown in FIGS. 1 to 14B may be fabricated.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An integrated circuit device comprising:
a lower insulating film arranged over a substrate;
a first lower metal wiring layer and a second lower metal wiring layer that extend through the lower insulating film in a vertical direction and are spaced apart from each other in a first horizontal direction, wherein a first local region of the lower insulating film is arranged between the first lower metal wiring layer and the second lower metal wiring layer;
an insulating etch stop layer comprising a first portion covering the first local region of the lower insulating film;
a via jumper contact unit, comprising a first contact surface contacting the first lower metal wiring layer, a second contact surface contacting the second lower metal wiring layer, and a third contact surface spaced apart from the first local region of the lower insulating film in the vertical direction, wherein the first portion of the insulating etch stop layer is arranged between the third contact surface and the first local region of the lower insulating film, and the third contact surface is arranged between the first contact surface and the second contact surface and contacts the first portion of the insulating etch stop layer; and
an upper metal wiring layer spaced apart from at least one of the first lower metal wiring layer or the second lower metal wiring layer in the vertical direction, wherein the via jumper contact unit is arranged between the upper metal wiring layer and the at least one of the first lower metal wiring layer or the second lower metal wiring layer, and the upper metal wiring layer is connected to the via jumper contact unit.

2. The integrated circuit device of claim 1, wherein each of the via jumper contact unit and the upper metal wiring layer has a gradually increasing width in the first horizontal direction with an increasing distance from the lower insulating film in the vertical direction.

3. The integrated circuit device of claim 1, wherein a vertical level of an uppermost surface of the insulating etch stop layer is higher than a vertical level of an uppermost surface of each of the first lower metal wiring layer and the second lower metal wiring layer, and
wherein, in the via jumper contact unit, a vertical level of the third contact surface is farther from the substrate than a vertical level of at least one of the first contact surface or the second contact surface.

4. The integrated circuit device of claim 1, wherein a vertical level of an uppermost surface of the insulating etch stop layer is same as a vertical level of an uppermost surface of each of the first lower metal wiring layer and the second lower metal wiring layer, and
wherein, in the via jumper contact unit, a vertical level of the third contact surface is same as a vertical level of at least one of the first contact surface or the second contact surface.

5. The integrated circuit device of claim 1, wherein a vertical level of an uppermost surface of the insulating etch stop layer is lower than a vertical level of an uppermost surface of each of the first lower metal wiring layer and the second lower metal wiring layer, and
wherein, in the via jumper contact unit, a vertical level of the third contact surface is closer to the substrate than a vertical level of at least one of the first contact surface or the second contact surface.

6. The integrated circuit device of claim 1, wherein the via jumper contact unit is in contact with an upper surface of each of the first lower metal wiring layer and the second lower metal wiring layer and is offset from sidewalls of each of the first lower metal wiring layer and the second lower metal wiring layer.

7. The integrated circuit device of claim 1, wherein the via jumper contact unit is in contact with an upper surface and at least one sidewall of each of the first lower metal wiring layer and the second lower metal wiring layer.

8. The integrated circuit device of claim 1, wherein the first lower metal wiring layer has a first outer sidewall farthest from the second lower metal wiring layer in the first horizontal direction, a first inner sidewall facing the second lower metal wiring layer in the first horizontal direction, and a first upper surface,
wherein the second lower metal wiring layer has a second outer sidewall farthest from the first lower metal wiring layer in the first horizontal direction, a second inner sidewall facing the first lower metal wiring layer in the first horizontal direction, and a second upper surface,
wherein a width of the via jumper contact unit in the first horizontal direction is greater than a distance in the first horizontal direction between the first outer sidewall of the first lower metal wiring layer and the second outer sidewall of the second lower metal wiring layer, and
wherein the via jumper contact unit is in contact with each of the first outer sidewall, the first inner sidewall, and the first upper surface of the first lower metal wiring layer and in contact with each of the second outer sidewall, the second inner sidewall, and the second upper surface of the second lower metal wiring layer.

9. The integrated circuit device of claim 1, wherein the first lower metal wiring layer has a first outer sidewall farthest from the second lower metal wiring layer in the first horizontal direction, a first inner sidewall facing the second lower metal wiring layer in the first horizontal direction, and a first upper surface,
wherein the second lower metal wiring layer has a second outer sidewall farthest from the first lower metal wiring layer in the first horizontal direction, a second inner sidewall facing the first lower metal wiring layer in the first horizontal direction, and a second upper surface,
wherein a width of the via jumper contact unit in the first horizontal direction is less than a distance in the first horizontal direction between the first outer sidewall of the first lower metal wiring layer and the second outer sidewall of the second lower metal wiring layer, and
wherein the via jumper contact unit is in contact with the first inner sidewall and the first upper surface of the first lower metal wiring layer and in contact with the second inner sidewall and the second upper surface of the second lower metal wiring layer, and is spaced apart from each of the first outer sidewall of the first lower metal wiring layer and the second outer sidewall of the second lower metal wiring layer.

10. The integrated circuit device of claim 1, comprising an upper insulating film arranged over the lower insulating film and covering sidewalls of each of the via jumper contact unit and the upper metal wiring layer,
wherein a first outer sidewall of the first lower metal wiring layer and a second outer sidewall of the second lower metal wiring layer each comprise a portion contacting the upper insulating film, wherein the first outer sidewall of the first lower metal wiring layer is farthest from the second lower metal wiring layer in the first horizontal direction, and the second outer sidewall of the second lower metal wiring layer is farthest from the first lower metal wiring layer in the first horizontal direction.

11. The integrated circuit device of claim 1, comprising an upper insulating film arranged over the lower insulating film and covering sidewalls of each of the via jumper contact unit and the upper metal wiring layer,
wherein a first outer sidewall of the first lower metal wiring layer, a first upper surface of the first lower metal wiring layer, a second outer sidewall of the second lower metal wiring layer, and a second upper surface of the second lower metal wiring layer each comprise a portion contacting the upper insulating film, wherein the first outer sidewall of the first lower metal wiring layer is farthest from the second lower metal wiring layer in the first horizontal direction, and the second outer sidewall of the second lower metal wiring layer is farthest from the first lower metal wiring layer in the first horizontal direction.

12. The integrated circuit device of claim 1, comprising a third lower metal wiring layer passing through the lower insulating film in the vertical direction and spaced apart from the second lower metal wiring layer, wherein a second local region of the lower insulating film is arranged between the third lower metal wiring layer and the second lower metal wiring layer,
wherein the insulating etch stop layer further comprises a second portion covering an upper surface of the second local region of the lower insulating film, and
the via jumper contact unit further comprises a fourth contact surface contacting the third lower metal wiring layer, and a fifth contact surface, which is spaced apart from the second local region of the lower insulating film in the vertical direction, wherein the second portion of the insulating etch stop layer is arranged between the fifth contact surface and the second local region of the lower insulating film, and the fifth contact surface is in contact with the second portion of the insulating etch stop layer.

13. The integrated circuit device of claim 1, comprising:
a first upper insulating film arranged on the insulating etch stop layer and contacting a portion of a sidewall of each of the first lower metal wiring layer and the second lower metal wiring layer; and
a second upper insulating film arranged on the first upper insulating film and covering sidewalls of each of the via jumper contact unit and the upper metal wiring layer,
wherein a vertical level of an uppermost surface of the insulating etch stop layer is lower than a vertical level of an uppermost surface of each of the first lower metal wiring layer and the second lower metal wiring layer, and
wherein, in the via jumper contact unit, a vertical level of the third contact surface is closer to the substrate than a vertical level of at least one of the first contact surface or the second contact surface.

14. The integrated circuit device of claim 13, comprising an upper insulating etch stop layer arranged between the first upper insulating film and the second upper insulating film,
wherein the upper insulating etch stop layer is in contact with a sidewall of the via jumper contact unit at a vertical level that is higher than a vertical level of an upper surface of each of the first lower metal wiring layer and the second lower metal wiring layer.

15. The integrated circuit device of claim 1, wherein the first portion of the insulating etch stop layer comprises at least two different material films.

16. The integrated circuit device of claim 1, wherein the lower insulating film comprises a peripheral local region that is spaced apart from the first local region, wherein the first lower metal wiring layer is arranged between the peripheral local region and the first local region,
wherein the insulating etch stop layer comprises a second portion that is spaced apart from the first portion in the first horizontal direction, wherein the first lower metal wiring layer is arranged between the second portion and the first portion, and the second portion covers the peripheral local region of the lower insulating film, and
wherein the first portion and the second portion of the insulating etch stop layer respectively have different thicknesses in the vertical direction.

17. The integrated circuit device of claim 1, wherein the lower insulating film comprises a peripheral local region that is spaced apart from the first local region, wherein the first lower metal wiring layer is arranged between the peripheral local region and the first local region,
wherein the insulating etch stop layer comprises a second portion that is spaced apart from the first portion in the first horizontal direction, wherein the first lower metal wiring layer is arranged between the second portion and the first portion, and the second portion covers the peripheral local region of the lower insulating film,
wherein the second portion of the insulating etch stop layer has a multilayer structure comprising at least three material films stacked in the vertical direction, and
wherein the first portion of the insulating etch stop layer has a single-layer structure comprising one material film or a double-layer structure including two different material films.

18. The integrated circuit device of claim 1, comprising an upper insulating film arranged over the lower insulating film and an insulating liner arranged between the via jumper contact unit and the upper insulating film and contacting each of the upper insulating film and the via jumper contact unit,
wherein the insulating liner and the insulating etch stop layer comprise a same material.

19. An integrated circuit device comprising:
a lower insulating film;
a plurality of lower metal wiring layers that extend through the lower insulating film in a vertical direction and are spaced apart from each other in a first horizontal direction;
an upper insulating film covering the lower insulating film and the plurality of lower metal wiring layers;
a via jumper contact unit comprising at least two contact portions and a contact connection portion, the at least two contact portions extending through the upper insulating film in the vertical direction and respectively contacting at least two lower metal wiring layers selected from the plurality of lower metal wiring layers, and the contact connection portion being connected to the at least two contact portions and overlapping a local region of the lower insulating film in the vertical direction; and
an insulating etch stop layer arranged between the local region of the lower insulating film and the contact connection portion of the via jumper contact unit.

20. An integrated circuit device comprising:
a lower insulating film arranged over a substrate;
a pair of lower metal wiring layers that extend through the lower insulating film in a vertical direction and are spaced apart from each other in a first horizontal direction, wherein a local region of the lower insulating film is arranged between the pair of lower metal wiring layers;
an insulating etch stop layer covering an upper surface of the lower insulating film and exposing respective upper surfaces of the pair of lower metal wiring layers;
an upper insulating film covering the lower insulating film, the pair of lower metal wiring layers, and the insulating etch stop layer; and
a via jumper contact unit comprising a pair of contact portions and a contact connection portion, the pair of contact portions extending through the upper insulating film in the vertical direction and respectively contacting the pair of lower metal wiring layers, and the contact connection portion being connected to the pair of contact portions and overlapping a local region of the lower insulating film in the vertical direction,
wherein the insulating etch stop layer comprises a first portion arranged between the local region of the lower insulating film and the contact connection portion of the via jumper contact unit, the first portion of the insulating etch stop layer being in contact with a lower surface of the contact connection portion of the via jumper contact unit.
